(19) United States
(12) Patent Application Publication
(10) Pub. No.: US 2015/0282386 A1
(43) Pub. Date: Oct. 1, 2015

(54) HEAT SOURCE UNIT OF REFRIGERATING APPARATUS

(71) Applicant: DAIKIN INDUSTRIES, LTD., Osaka (JP)

(72) Inventor: Hironori HAYAKAWA, Osaka (JP)

(73) Assignee: DAIKIN INDUSTRIES, LTD., Osaka (JP)

(21) Appl. No.: 14/228,093

(22) Filed: Mar. 27, 2014

(51) Int. Cl. H05K 7/20

(52) U.S. Cl. CPC H05K 7/20254; H05K 7/20272

(57) ABSTRACT

A heat source unit of a refrigerating apparatus includes a heat exchanger, an actuator, an electrical component controlling the actuator, a casing, and a partitioning plate. The casing has bottom and top plates with a vent on the top plate. The heat exchanger has first, second, third and fourth side face parts. The actuator is disposed in a first space surrounded by the first to fourth side face parts, and the partitioning plate. The electronic component is disposed in a second space partitioned from the first space by the partitioning plate. The second space is in a corner formed by the first and second side face parts. The partitioning plate is positioned between end parts of the first and fourth side face parts, and at least a portion is inserted between the bottom and top plates and fixed in a placed state.

### TECHNICAL FIELD

The present invention relates to a heat source unit of a refrigerating apparatus.

### BACKGROUND ART

Heat source units of a refrigerating apparatus typically have a partitioning plate provided inside a casing.

### SUMMARY OF THE INVENTION

In the heat source unit as described above, there is a case where the partitioning plate must be placed after placing the bottom plate and the top plate in the manufacturing process. In this case, the operation of placing the partitioning plate is difficult.

Therefore, with a heat source unit of the present invention, at least a portion of a partitioning plate is inserted from the side direction with regard to a main face of the partitioning plate in a placed state, and then fixed.

Specifically, a heat source unit of a refrigerating apparatus according to a first aspect comprises a heat exchanger, an actuator, an electrical component, a casing, and a partitioning plate. The electrical component controls driving of an actuator. The casing houses the heat exchanger, actuator, and electrical component. The partitioning plate is placed inside the casing. The casing has a bottom plate and a top plate. A vent for venting air upward is formed on the top plate. The heat exchanger has a first side face part, a second side face part, a third side face part, and a fourth side face part. The second side face part adjoins the first side face part. The third side face part opposes the first side face part and adjoins the second side face part. The fourth side face part opposes the second side face part and adjoins the third side face part. The first side face part faces a first side face of the casing. The fourth side face part faces a second side face of the casing. An end part of the first side face part configures one end of the heat exchanger. An end part of the fourth side face part configures the other end of the heat exchanger. The actuator is placed in a first space. The first space is a space enclosed by the first side face part, the second side face part, the third side face part, the fourth side face part, and the partitioning plate. The electrical component is placed in a second space. The second space is a space partitioned from the first space by the partitioning plate. The second space is positioned in a corner formed by the first side face and the second side face. The partitioning plate is positioned between the end part of the first side face part and the end part of the fourth side face part. When the partitioning plate is placed, the partitioning plate is fixed after at least a portion thereof is inserted between the bottom plate and the top plate from the side direction with regard to the main surface of the partitioning plate in a placed state.

In the heat source unit of a refrigerating apparatus according to the first aspect, when the partitioning plate is placed, the partitioning plate is fixed after at least a portion thereof is inserted between the bottom plate and the top plate from the side direction with regard to the main surface of the partitioning plate in a placed state. Therefore, even if the partitioning plate is placed after the bottom plate and the top plate have been placed, the partitioning plate can be easily placed. Consequently, placement of the partitioning plate is easy, and the production efficiency for manufacturing the heat source unit is improved.

A heat source unit of a refrigerating apparatus according to a second aspect is the heat source unit of a refrigerating apparatus according to the first aspect, wherein the partitioning plate has a first part. The first part is a flat member. The first part is inserted in a direction along the main face of the partitioning plate in a placed state.

In the heat source unit of a refrigerating apparatus according to the second aspect, placement of the partitioning plate is easy by the simple configuration.

Here, “the direction along the main face of the partitioning plate in a placed state” include not only the strict same direction with regard to the direction that the main face extends when the partitioning plate is in a placed state, but also directions that are slightly inclined with regard to the direction that the main face extends when the partitioning plate is in a placed state. Specifically, it is understood that the direction where the angle to the main face of the partitioning plate in a placed state is within a range of 0° to 30° in a planar view is included in “the direction along the main face of the partitioning plate in a placed state.”

A heat source unit of a refrigerating apparatus according to a third aspect is the heat source unit of a refrigerating apparatus according to the second aspect, wherein the first part is inserted at an angle with regard to the main face of the partitioning plate in a placed state. The first part is moved to the placement position by rotating around a vertical axis in the placed state, after being inserted.

In the heat source unit of a refrigerating apparatus according to the third aspect, placement of the partitioning plate is easy by the simple configuration.

A heat source unit of a refrigerating apparatus according to a fourth aspect is the heat source unit of a refrigerating apparatus according to the third aspect, wherein the first part has a handle. The handle is used when the first part is being rotated after being inserted.

In the heat source unit of a refrigerating apparatus according to the fourth aspect, the first part has a handle. Therefore, rotating the first part to the placement position after inserting is easy. Consequently, placement of the partitioning plate is even easier.

A heat source unit of a refrigerating apparatus according to a fifth aspect is the heat source unit of a refrigerating apparatus according to the second aspect, wherein the partitioning plate also has a second part. The second part is a member supporting the first part. The second part has a larger contour than the first part. The second part is placed before the first part is placed. When the second part is placed, the second part is inserted between the bottom plate and the top plate from the front face side with regard to the main face of the partitioning plate in a placed state. The second part is rotated with regard to a horizontal axis in the placed state, after being inserted between the bottom plate and the top plate. The second part is moved to the placement position by rotating around the horizontal axis in the placed state, and then fixed.

In the heat source unit of a refrigerating apparatus according to the fifth aspect, the partitioning plate also has a second part that is different from the first part. In other words, the partitioning plate has a split structure that is divided into the first part and the second part, and the first part and the second part are placed individually. Therefore, placement of the partitioning plate is even easier.

A heat source unit of a refrigerating apparatus according to a sixth aspect is the heat source unit of a refrigerating apparatus according to the third aspect, wherein the partitioning plate also has a second part. The second part is a member supporting the first part. The second part has a larger contour than the first part. The second part is placed before the first part is placed. When the second part is placed, the second part is inserted between the bottom plate and the top plate from the front face side with regard to the main face of the partitioning plate in a placed state. The second part is rotated with regard to a horizontal axis in the placed state, after being inserted between the bottom plate and the top plate. The second part is moved to the placement position by rotating around the horizontal axis in the placed state, and then fixed.

In the heat source unit of a refrigerating apparatus according to the sixth aspect, the partitioning plate also has a second part that is different from the first part. In other words, the partitioning plate has a split structure that is divided into the first part and the second part, and the first part and the second part are placed individually. Therefore, placement of the partitioning plate is even easier.

A heat source unit of a refrigerating apparatus according to a seventh aspect is the heat source unit of a refrigerating apparatus according to the sixth aspect, wherein an insertion opening into which the first part is inserted is formed in the second part. The first part is inserted in the second part through the insertion opening. The first part is fixed to the second part after being inserted in the second part.

In the heat source unit of a refrigerating apparatus according to the seventh aspect, placement of the partitioning plate is even easier.

A heat source unit of a refrigerating apparatus according to an eighth aspect is the heat source unit of a refrigerating apparatus according to the seventh aspect, wherein a first opening is formed in the main face of the second part. The first opening is smaller than an area of the main face of the first part. The first part is fixed to a plate surface on the first space side of the second part. The first part is exposed through the first opening from the first space side to the second space side. The first part has a handle. The handle is used when the first part is being rotated after being inserted. The handle has a protrusion. The protrusion is located at a height at which contact is made with the edge of the first opening when the first part is rotated and moved. The protrusion has a curved surface shaped so as to slide on the edge of the first opening.

In the heat source unit of a refrigerating apparatus according to the eighth aspect, the first part has a handle, and the handle has a protrusion. Therefore, placement of the partitioning plate is even easier, In other words, rotating the first part to the placement position after inserting is easy because the first part has a handle. Furthermore, when the protrusion contacts the edge of the first opening while the first part is rotated and moved using the handle, the protrusion slides over the edge of the first opening by continuously rotating because of having the curved surface. After sliding over the edge of the first opening, the protrusion suppresses rotation and movement of the first part from the placement position by contacting the edge of the first opening. Therefore, placement of the partitioning plate is even easier.

A heat source unit of a refrigerating apparatus according to a ninth aspect is the heat source unit of a refrigerating apparatus according to the first aspect, wherein a refrigerant pipeline is placed in the second space. The refrigerant pipeline adjoins the partitioning plate.

In the heat source unit of a refrigerating apparatus according to the ninth aspect, the partitioning plate can be easily placed even in a state where placing the partitioning plate is difficult because of existence of a structure such as the refrigerant pipeline or the like.

A heat source unit of a refrigerating apparatus according to a tenth aspect is the heat source unit of a refrigerating apparatus according to the ninth aspect, wherein the electrical component is mounted on a substrate. The substrate is fixed to the partitioning plate. The substrate has a heat sink. The refrigerant pipeline is in contact with the heat sink.

In the heat source unit of a refrigerating apparatus according to the tenth aspect, placement of the partitioning plate is easy, even in a state where the partitioning plate is difficult to place.

A heat source unit of a refrigerating apparatus according to an eleventh aspect is the heat source unit of a refrigerating apparatus according to the tenth aspect, wherein the refrigerant pipeline has a vertical part. The vertical part is a part that extends in the vertical direction.

In the heat source unit of a refrigerating apparatus according to the eleventh aspect, placement of the partitioning plate is easy, even in a state where the partitioning plate is difficult to place.

A heat source unit of a refrigerating apparatus according to a twelfth aspect is the heat source unit of a refrigerating apparatus according to the first aspect, wherein the partitioning plate is fixed after the whole part is inserted between the bottom plate and the top plate from the side with regard to the main surface of the partitioning plate in a placed state, when the partitioning plate is placed.

In the heat source unit of a refrigerating apparatus according to the twelfth aspect, placement of the partitioning plate is easy when the partitioning plate is placed after placing the bottom plate and the top plate. Therefore, placing of the partitioning plate is easy, and the production efficiency for manufacturing the heat source unit is improved.

A heat source unit for a refrigerating apparatus according to a thirteenth aspect is the heat source unit of a refrigerating apparatus according to the twelfth aspect, wherein the partitioning plate is inserted at an angle with regard to the main face of the partitioning plate in a placed state. The partitioning plate is moved to the placement position by rotating around a vertical axis in the placed state after being inserted.

In the heat source unit of a refrigerating apparatus according to the thirteenth aspect, placement of the partitioning plate is easy by the simple configuration.

### BRIEF DESCRIPTION OF THE DRAWINGS

FIG. 1 is a schematic diagram of an air-conditioning apparatus including a heat source unit according to one embodiment of the present invention.

FIG. 2 is an external perspective view of the heat source unit according to one embodiment of the present invention.

FIG. 3 is a sectional view along A-A in FIG. 2 (some machines and devices housed inside the casing are not illustrated).

FIG. 4 is a diagram typically illustrating the heat source unit viewed from above.

FIG. 5 is an external perspective view of the heat source-side heat exchanger.

FIG. 6 is an external perspective view of the heat source unit in a condition having removed the first corner cover.

FIG. 7 is an external view of the first plate in a state having the substrate fixed.

FIG. 8 is an external view of the second plate.

FIG. 9 is an external perspective view of the heat source unit in a state having removed the partitioning plate from the condition in FIG. 6.

FIG. 10 is a front surface perspective view of an upper guard member.

FIG. 11 is a back surface perspective view of an upper guard member.

FIG. 12 is a front surface perspective view of a lower guard member.

FIG. 13 is a back surface perspective view of a lower guard member.

FIG. 14 is a diagram schematically illustrating a form of inserting the second plate into the casing in the state illustrated in FIG. 9.

FIG. 15 is an enlarged diagram schematically illustrating a form of inserting the second plate into the casing in the state illustrated in FIG. 9.

FIG. 16 is a right side surface view schematically illustrating a form of moving the second plate in a rotational manner to the placement position after inserting into the casing in the state illustrated in FIG. 9.

FIG. 17 is a front surface view illustrating the second plate, the guard member, and the fifth refrigerant pipeline in a placed condition.

FIG. 18 is a diagram schematically illustrating a form of inserting the first plate into the second plate in the state illustrated in FIG. 17.

FIG. 19 is a diagram schematically illustrating a form of further inserting the first plate into the second plate in the state illustrated in FIG. 18.

FIG. 20 is a sectional view along B-B in FIG. 19.

FIG. 21 is a schematic view highlighting and illustrating the insertion direction of the first plate, and the main face of the partitioning plate in the placed state in FIG. 20.

FIG. 22 is a front surface view illustrating the partitioning plate, the guard member, and the fifth refrigerant pipeline in a placed condition.

FIG. 23 is a sectional view along C-C in FIG. 22.

FIG. 24 is a schematic view viewing the handle from the lower face in FIG. 22.

FIG. 25 is a schematic view viewing the handle from the left side face in FIG. 22.

FIG. 26 is an external perspective view of the partitioning plate according to modified example D.

FIG. 27 is a sectional view along D-D in FIG. 26.

FIG. 28 is a diagram schematically illustrating a form of inserting the partitioning plate according to modified example D into the casing in the state illustrated in FIG. 9.

FIG. 29 is a diagram illustrating a condition where the partitioning plate according to modified example D is placed in the casing in the state illustrated in FIG. 9.

FIG. 30 is an external perspective view of the substrate retaining member according to modified example D.

FIG. 31 is a diagram illustrating an aspect where the substrate retaining member according to modified example D is placed on the partitioning plate in the state illustrated in FIG. 29.

FIG. 32 is a diagram illustrating a condition where the substrate retaining member according to modified example D is placed on the partitioning plate in the state illustrated in FIG. 29.

### DESCRIPTION OF EMBODIMENTS

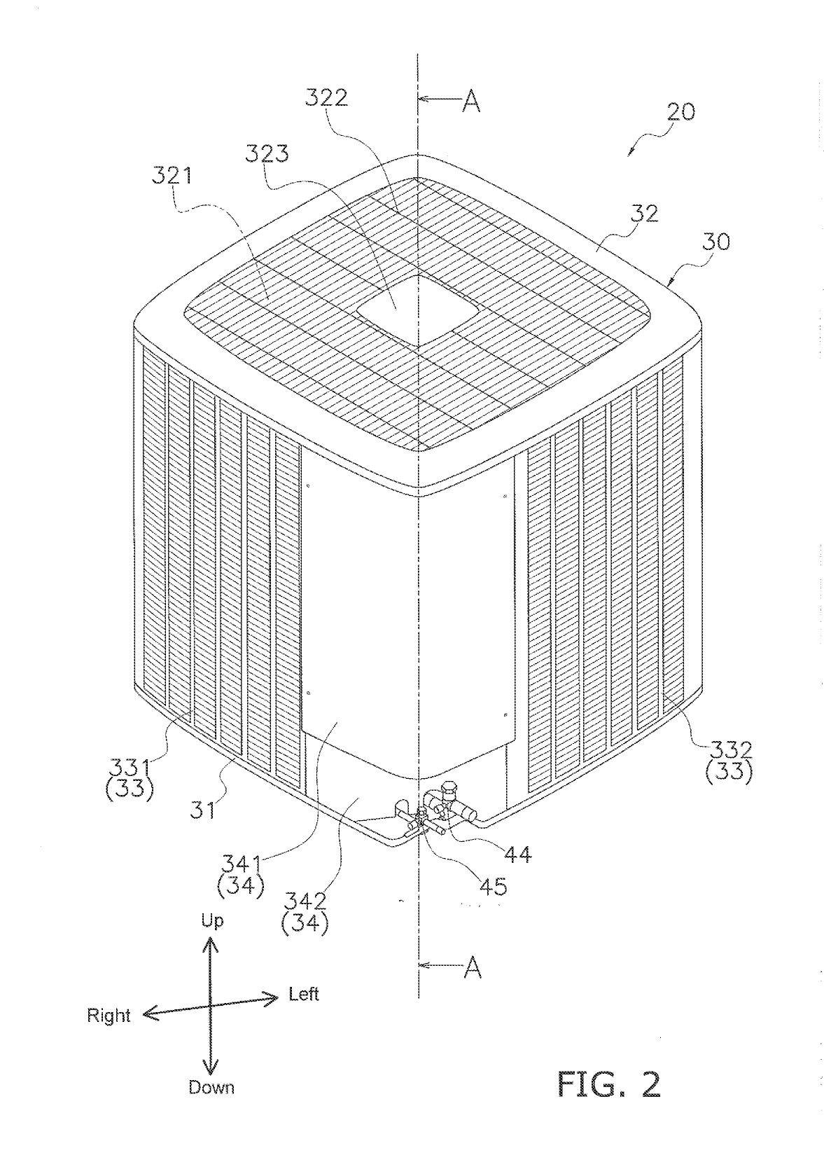

A heat source unit 20 according to one embodiment of the present invention is described below. The embodiment below is a specific example of the present invention and is not a limitation of the technical scope of the present invention. Suitable modifications may be made within a scope not deviating from the gist of the invention. In the embodiment below, the directions “up,” “down,” “front (front face),” “back (back face),” “left,” and “right” signify the directions illustrated in FIGS. 2 to 25. These directions are directions based on a main face 50a of a partitioning plate 50 (to be described) in a placed state.

(1) Configuration of the Air-Conditioning Apparatus 100

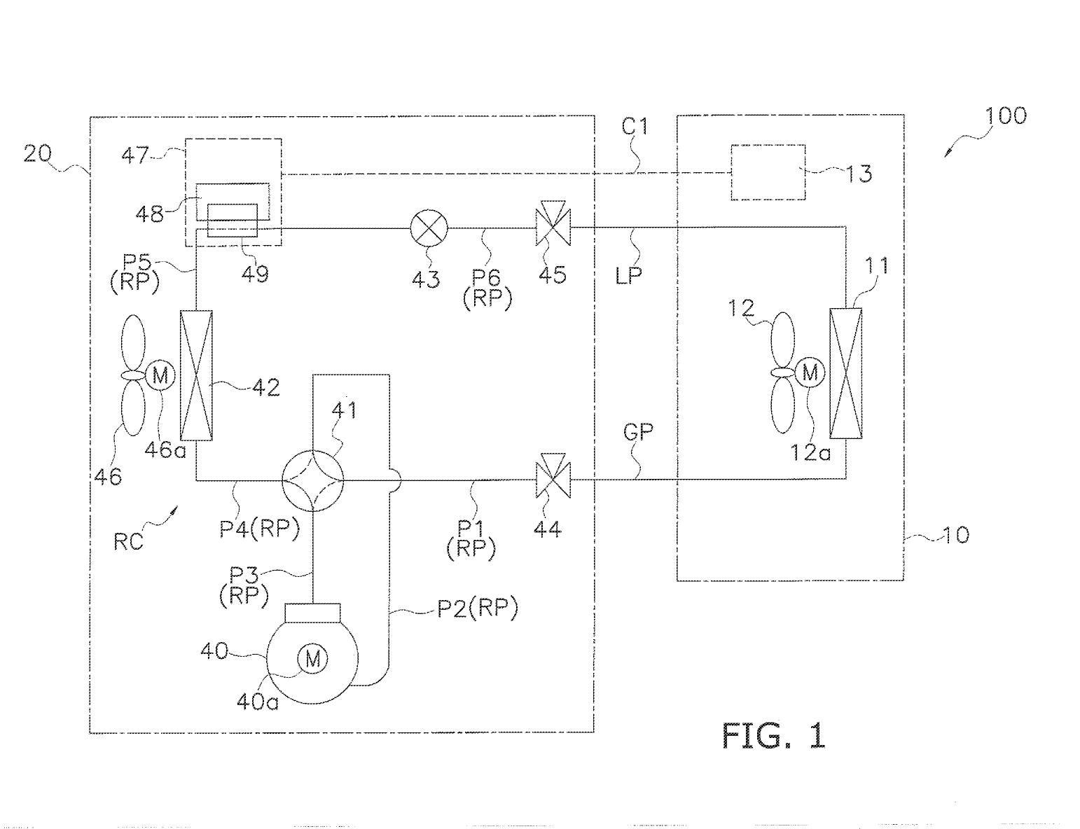

FIG. 1 is a schematic diagram of an air-conditioning apparatus 100 including a heat source unit 20 according to one embodiment of the present invention.

The air-conditioning apparatus 100 is an apparatus for performing a cooling operation or a warming operation to realize air conditioning of an object space. Specifically, the air-conditioning apparatus 100 performs a vapor compression-type refrigeration cycle. In the air-conditioning apparatus 100, a refrigerant circuit RC is configured mainly by connection of a utilization unit 10 and a heat source unit 20. The utilization unit 10 and the heat source unit 20 are connected by way of a liquid refrigerant connection pipe LP and a gas refrigerant connection pipe GP.

<Utilization Unit 10>

The utilization unit 10 is placed indoors. The utilization unit 10 mainly has a utilization-side heat exchanger 11, a utilization unit blower 12, and a utilization unit controller 13.

The utilization-side heat exchanger 11 is a heat exchanger that functions as an evaporator of refrigerant during the cooling operation and functions as a condenser or a radiator of refrigerant during the warming operation. A liquid side of the utilization-side heat exchanger 11 is connected to the liquid refrigerant connection pipe LP, and a gas side of the utilization-side heat exchanger 11 is connected to a gas refrigerant connection pipe GP.

The utilization unit blower 12 is a blower for generating an air flow that flows into the utilization unit 10 from outside the utilization unit 10, passes through the utilization-side heat exchanger 11, and then flows out of the utilization unit 10. The utilization unit blower 12 is connected to an output shaft of a utilization unit blower motor 12a, and drives in unison with operation of the utilization unit blower motor 12a.

The utilization unit controller 13 is a microcomputer including a CPU, memory, and/or the like. The utilization unit controller 13 is connected with a heat source unit controller 47 by way of a communication cable C1, and signals are mutually exchanged in accordance with the situation. The utilization unit 10 also exchanges signals with a remote controller (not illustrated).

<Heat Source Unit 20>

The heat source unit 20 is placed outdoors, in a basement, and/or the like. The heat source unit 20 mainly has refrigerant piping RP, a compressor 40, a four-way switching valve 41, a heat source-side heat exchanger 42, an expansion valve 43, a gas-side closing valve 44, a liquid-side closing valve 45, a heat source unit blower 46, and the heat source unit controller 47, and these machines and devices are housed inside a casing 30 (to be described).

The refrigerant piping RP placed in the heat source unit 20 mainly include first refrigerant piping P1, second refrigerant piping P2, third refrigerant piping P3, fourth refrigerant piping P4, fifth refrigerant piping P5, and sixth refrigerant piping P6. One end of the first refrigerant piping P1 is connected to the gas-side closing valve 44, and the other end is connected to the four-way switching valve 41. One end of the second refrigerant piping P2 is connected to the four-way switching valve 41, and the other end is connected to an intake port of the compressor 40. One end of the third refrigerant piping P3 is connected to a discharge port of the compressor 40, and the other end is connected to the four-way switching valve 41. One end of the fourth refrigerant piping P4 is connected to the four-way switching valve 41, and the other end is connected to the heat source-side heat exchanger 42. One end of the fifth refrigerant piping P5 (equivalent to “refrigerant pipe line” in the claims) is connected to the heat source-side heat exchanger 42, and the other end is connected to the expansion valve 43. The fifth refrigerant piping P5 passes through a heat sink. 49 (to be described) between the one end and the other end. One end of the sixth refrigerant piping P6 is connected to the expansion valve 43, and the other end is connected to the liquid-side closing valve 45.

The compressor 40 is a machine for compressing a refrigerant. The compressor 40 drives in unison with operation of a compressor motor 40a. The compressor motor 40a is a motor of a type in which the frequency (rotation rate) is controllable by an inverter. The compressor 40 is configured so that an operating capacity can be controlled by varying a frequency (rotation rate).

The four-way switching valve 41 is a switching valve for switching the direction of flow of the refrigerant in the refrigerant circuit RC. In the present embodiment, the four-way switching valve 41 is a four-way valve connected to the first refrigerant piping P1, the second refrigerant piping P2, the third refrigerant piping P3, and the fourth refrigerant piping P4. The four-way switching valve 41 connects the first refrigerant piping P1 and the second refrigerant piping P2, and connects the third refrigerant piping P3 and the fourth refrigerant piping P4 during the cooling operation (see the solid line of the four-way switching valve 41 in FIG. 1). The four-way switching valve 41 connects the first refrigerant piping P1 and the third refrigerant piping P3, and connects the second refrigerant piping P2 and the fourth refrigerant piping P4 during the warming operation (see the broken line of the four-way switching valve 41 in FIG. 1).

The heat source-side heat exchanger 42 is a heat exchanger that functions as a condenser or a radiator of refrigerant during the cooling operation and functions as an evaporator of refrigerant during the warming operation. A gas side of the heat source-side heat exchanger 42 is connected to the fourth refrigerant piping P4, and a liquid side is connected to the fifth refrigerant piping P5. The configuration of the heat source-side heat exchanger 42. is to be described.

The expansion valve 43 is a valve for depressurizing a high-pressure refrigerant. The expansion valve 43 depressurizes the high-pressure refrigerant condensed or radiated in the heat source-side heat exchanger 42. during the cooling operation. The expansion valve 43 depressurizes the high-pressure refrigerant condensed or radiated in the utilization-side heat exchanger 11 during the warming operation.

The gas-side closing valve 44 and the liquid-side closing valve 45 are manually-operated valves that are closed during pump down, or the like. One end of the gas-side closing valve 44 is connected to the gas refrigerant connection pipe GP, and the other end is connected to the first refrigerant piping P1. One end of the liquid-side closing valve 45 is connected to the liquid refrigerant connection pipe LP, and the other end is connected to the sixth refrigerant piping P6.

The heat source unit blower 46 is, for example, a propeller fan or other blower. The heat source unit blower 46 generates an air flow that flows into the casing 30 from outside the casing 30, passes through the heat source-side heat exchanger 42, and then flows out of the casing 30 by way of a vent 321. The heat source unit blower 46 is connected to an output shaft of a heat source unit blower motor 46a, and drives in unison with operation of the heat source unit blower motor 46a.

The heat source unit controller 47 controls the operation of the compressor motor 40a and of other actuators included in the heat source unit 20. The heat source unit controller 47 is a unit having a microcomputer including a CPU, memory, and/or the like, and/or various other electrical components such as an inverter. The heat source unit controller 47 is mounted on a substrate 47a. A power element or other heat-generating part 48 that generates heat by electrical conduction is included in the electrical components of the heat source unit controller 47. A heat sink 49 is provided on the substrate 47a for cooling this heat-generating part 48.

The heat sink 49 is a heat exchanger that cools the heat-generating part 48 using a refrigerant (herein the refrigerant flowing through the fifth refrigerant pipeline PS) that circulates through the refrigerant circuit RC. Specifically, the heat sink 49 functions as a heat exchanger that cools the heat-generating part 48 using refrigerant that passes through the heat source-side heat exchanger 42 during the cooling operation, and functions as a heat exchanger that cools the heat-generating part 48 using refrigerant that passes through the expansion valve 43 during the warming operation.

(2) Details of the Heat Source Unit 20 and Parts Disposed Inside the Heat Source Unit 20

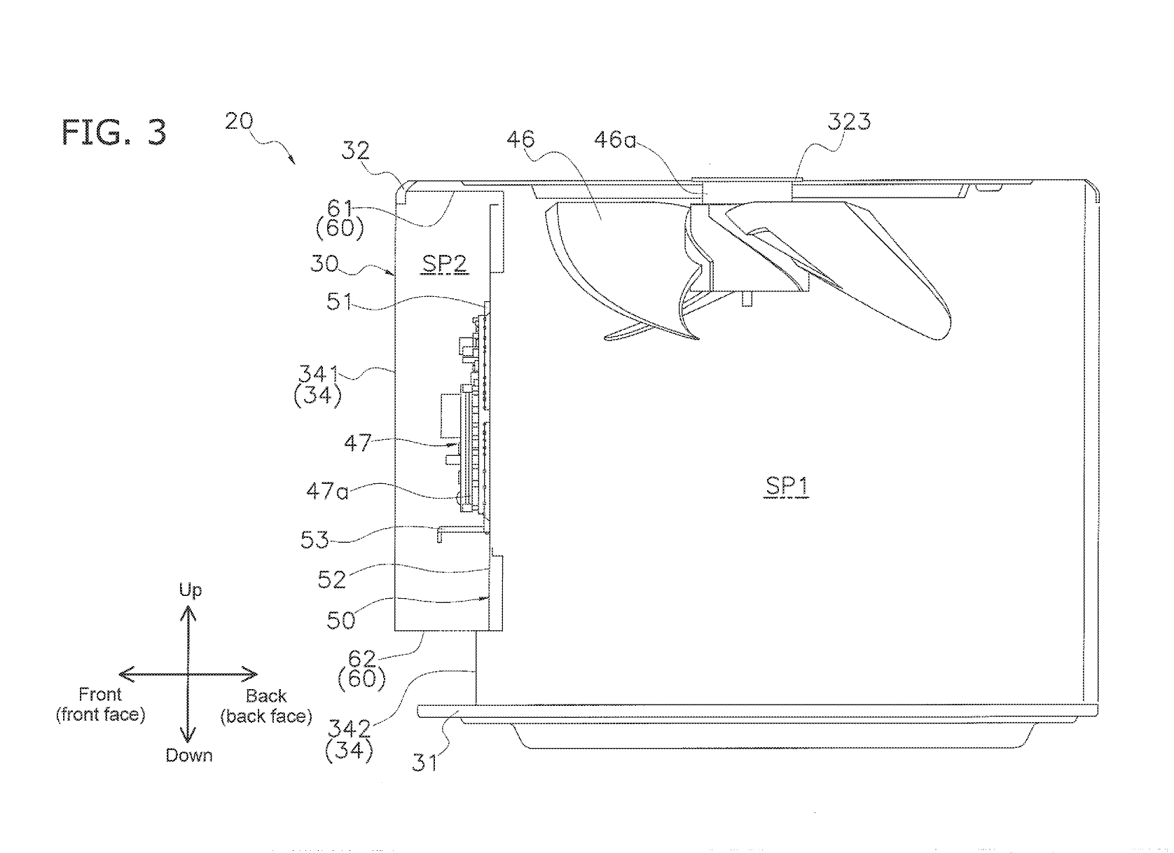

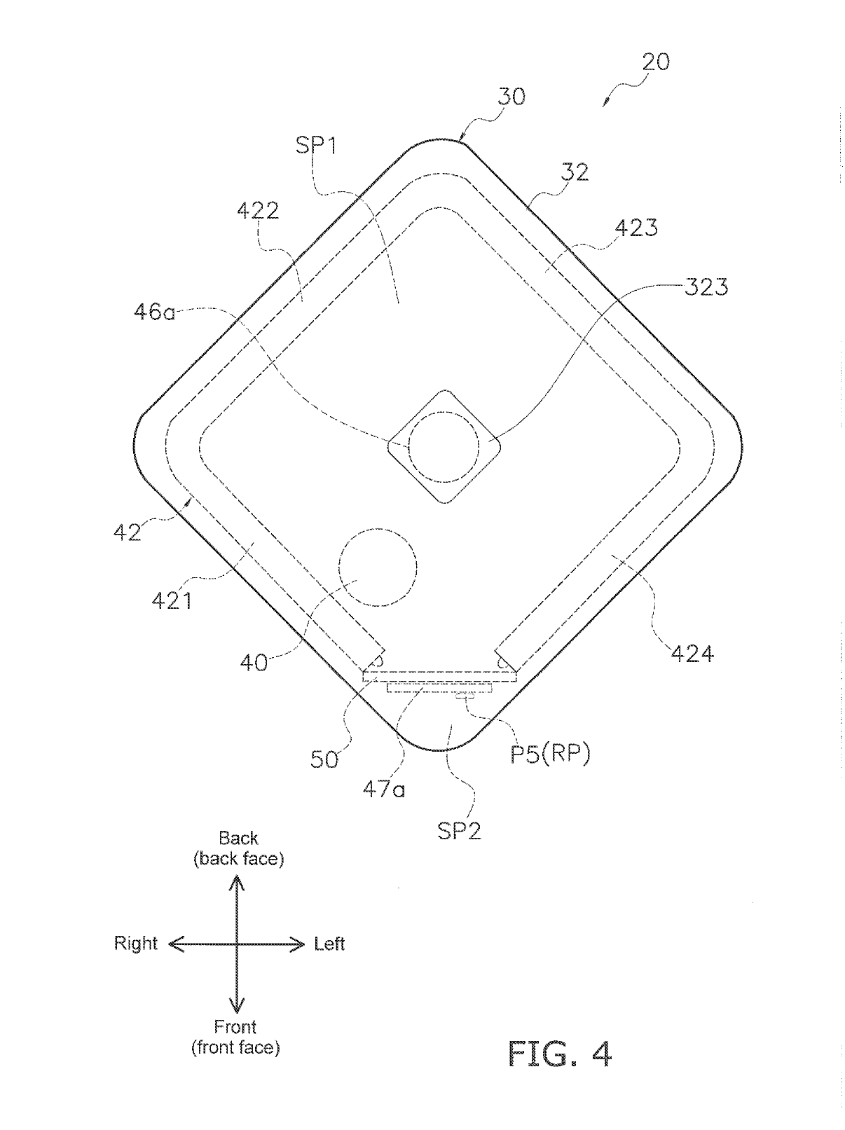

The heat source unit 20 and various parts disposed inside the heat source unit 20 shall now be described in detail. FIG. 2 is an external perspective view of the heat source unit 20 according to one embodiment of the present invention. FIG. 3 is a sectional view along A-A in FIG. 2 (some machines and devices housed inside the casing 30 are not illustrated). FIG. 4 is a diagram typically illustrating the heat source unit 20 viewed from above.

<Casing 30>

The outline of the heat source unit 20 is configured from a roughly parallelepiped-form casing 30, and various machines and devices are housed inside the casing 30. The partitioning plate 50 is placed inside the casing 30. The partitioning plate 50 is described below. The casing 30 mainly has a bottom plate 31, a top plate 32, a side face grill 33, and a corner cover 34.

The bottom plate 31 is a roughly square plate-form member configuring a bottom face portion of the casing 30. The partitioning plate 50 is placed on top of the bottom plate 31. A plurality of ribs (not illustrated) is formed on the bottom plate 31 for the purpose of forming drainage channels for drain water, providing strength to the bottom plate 31 and/or other purposes.

The top plate 32 is a roughly square plate-form member configuring a top face portion of the casing 30. The top plate 32 has a large opening functioning as a vent 321 for air. The reason why the vent 321 is formed in the top plate 32 is because the direction of blowing air of the heat source unit 20 is upward. That is, the heat source unit 20 is configured so as to discharge air upward by way of the vent 321 after having taken air into the casing 30 from four side faces during operation. A lattice-form member 322 is provided on the vent 321 for the purpose of preventing articles from falling in, or the like. The lattice-form member 322 configures a portion of the top plate 32. A plate-form motor installation part 323 is provided in the center portion of the top plate 32. The plate-form motor installation part 323 configures a portion of the top plate 32. The heat source unit blower motor 46a is fixed on the lower face side of the motor installation part 323. That is, the heat source unit blower motor 46a is fixed to the top plate 32.

The side face grill 33 is a lattice-form member configuring four side faces of the casing 30. The side face grill 33 includes a first side face grill 331 and a second side face grill 332. The first side face grill 331 configures one side face (equivalent to “first side face” in the claims) among the four side faces of the casing 30. The second side face grill 332 configures another one side face (equivalent to “second side face” in the claims). More specifically, the second side face grill 332 configures a side face adjacent to the side face configured by the first side face grill 331.

The corner cover 34 is a plate-form member covering a corner portion formed by the side face configured by the first side face grill 331 and the side face configured by the second side face grill 332. In other words, the corner cover 34 can be considered as a member connecting one end of the first side face grill 331 and one end of the second side face grill 332. More specifically the corner cover 34 is fixed by screws to the first side face grill 331 and the second side face grill 332. The corner cover 34 includes a first corner cover 341 and a second corner cover 342.

The first corner cover 341 is a plate-form member having a roughly L shape or a roughly V shape in planar view. The first corner cover 341 shields an electrical components compartment SP2 (to be described) from the outside. The second corner cover 342 is a plate-form member placed further below from the first corner cover 341. The second corner cover 342 is placed on the bottom plate 31. The second corner cover 342 shields the machine compartment SP1 from the outside below the electrical components compartment SP2. An opening for exposing the gas-side closing valve 44 and the liquid-side closing valve 45 is formed on the second corner cover 342.

<Heat Source-Side Heat Exchanger 42>

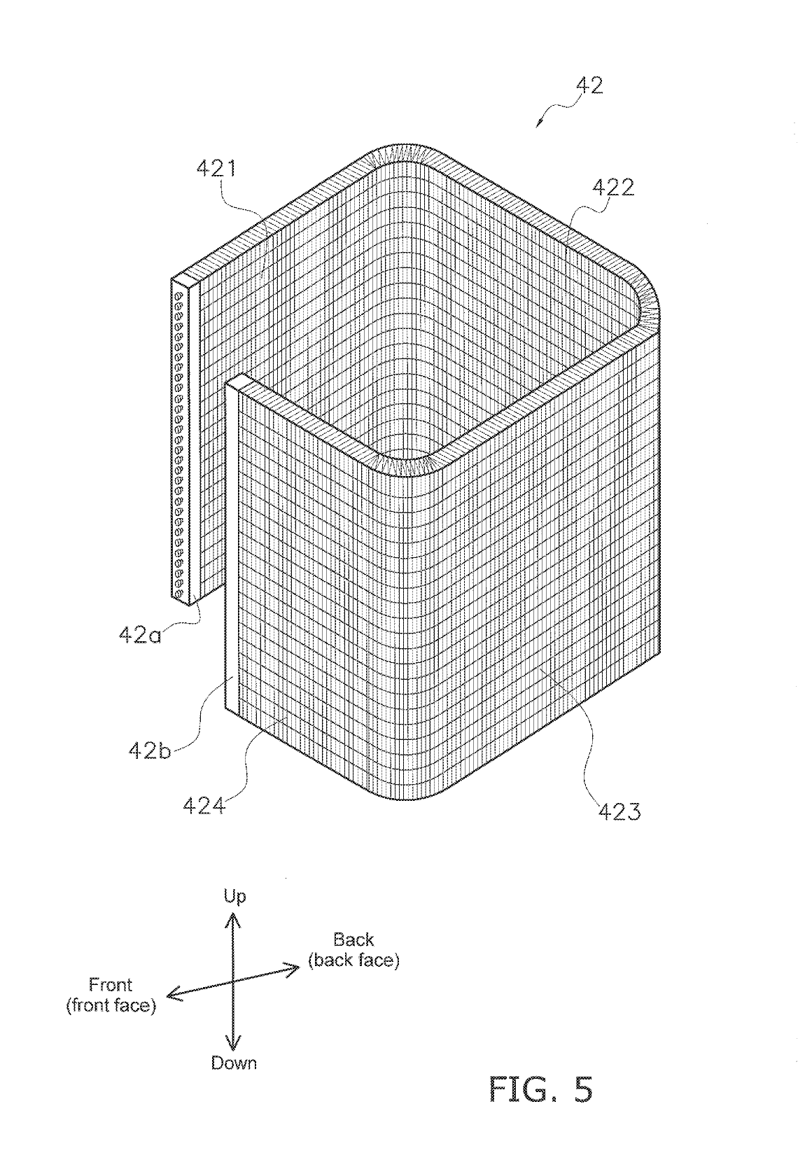

FIG. 5 is an external perspective view of the heat source-side heat exchanger 42. The heat source-side heat exchanger 42 is a fin-and-tube heat exchanger including a plurality of heat-transmitting tubes and a plurality of fins. The heat source-side heat exchanger 42 has four side face parts facing the side faces of the casing 30, and two tube plates. Specifically, the heat source-side heat exchanger 42 has a first side face part 421, a second side face part 422, a third side face part 423, a fourth side face part 424, a first tube plate 42a, and a second tube plate 42b.

The first side face part 421 faces the side face that is configured by the first side face grill 331. The second side face part 422 faces a side face that is adjacent to the side face configured by the first side face grill 331. That is, the second side face part 422 adjoins the first side face part 421. The third side face part 423 faces a side face that is opposite the side face faced by the first side face part 421 and is adjacent to the side face faced by the second side face part 422. That is, the third side face part 423 opposes the first side face part 421 and adjoins the second side face part 422. The fourth side face part 424 faces the side face that is configured by the second side face grill 332. The fourth side face part 424 also faces a side face that is opposite the side face faced by the second side face part 422 and is adjacent to the side face faced by the third side face part 423. That is, the fourth side face part 424 opposes the second side face part 422 and adjoins the third side face part 423. The fourth side face part 424 is not adjacent to the first side face part 421.

The first tube plate 42a is fixed to an end part of the first side face part 421. The second tube plate 42b is fixed to an end part of the fourth side face part 424. Screw holes (not illustrated) for fixing a second plate 52 (to be described) and a guard member 60 (to be described) are formed on the first tube plate 42a and the second tube plate 42b.

In the heat source-side heat exchanger 42, as illustrated in FIGS. 4 and 5, the end part of the first side face part 421 (that is, the first tube plate 42a) configures one end of the heat source-side heat exchanger 42, and the end part of the fourth side face part 424 (that is, the second tube plate 42b) configures the other end of the heat source-side heat exchanger 42. A space is present between the end part of the first side face part 421 and the end part of the fourth side face part 424, and the partitioning plate 50 and the guard member 60 are placed that space.

<Machine Compartment SP1 and Electrical Components Compartment SP2>

Two spaces are formed by placement of the partitioning plate 50 inside the casing 30. Specifically, the machine compartment SP1 is the space formed on the back face side of the partitioning plate 50. Furthermore, the electrical components compartment SP2 is the space formed on the front face side of the partitioning plate 50.

The machine compartment SP1 is a space occupying the larger portion inside of the casing 30 as illustrated in FIG. 4. Specifically, the machine compartment SP1 is surrounded by the heat source-side heat exchanger 42 (that is, the first side face part 421, the second side face part 422, the third side face part 423, and the fourth side face part 424) and the partitioning plate 50. Actuators such as the compressor 40 and four way switching valve 41, a refrigerant pipeline RP, and/or the like, are disposed in the machine compartment SP1.

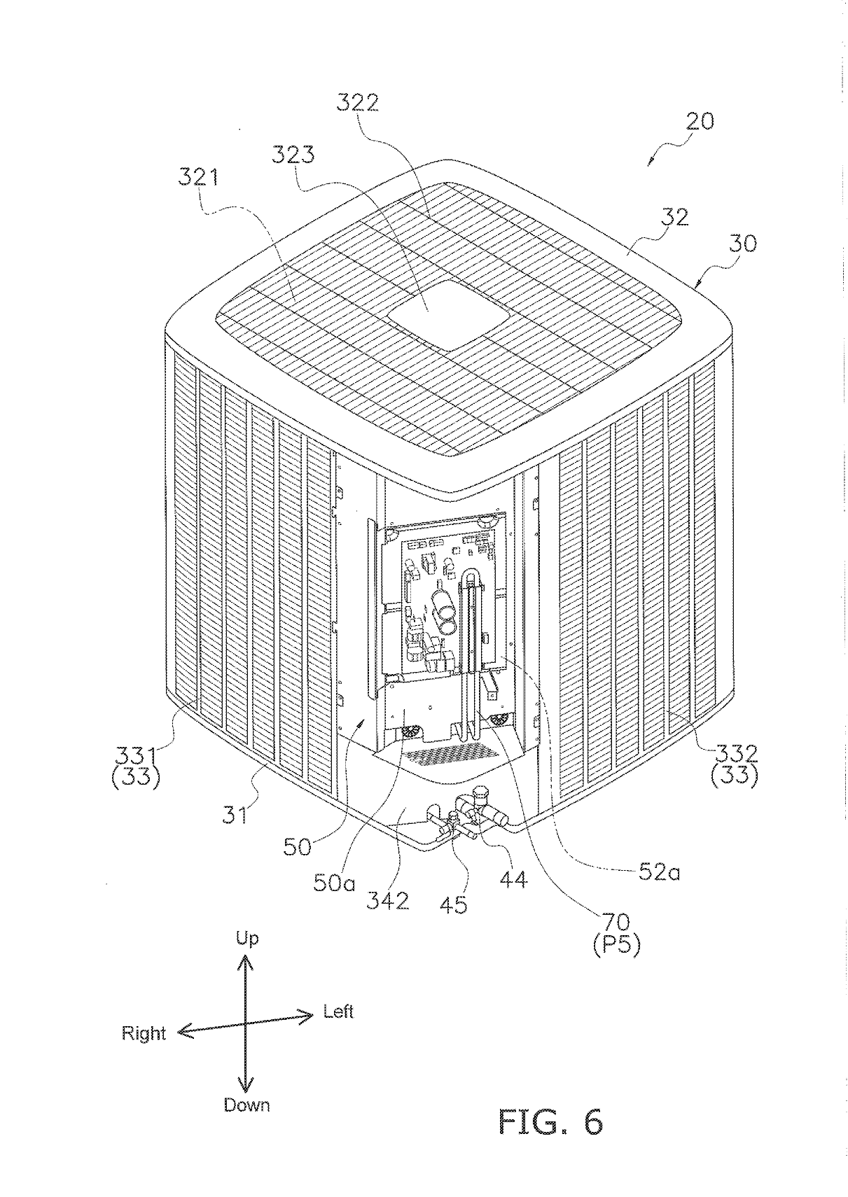

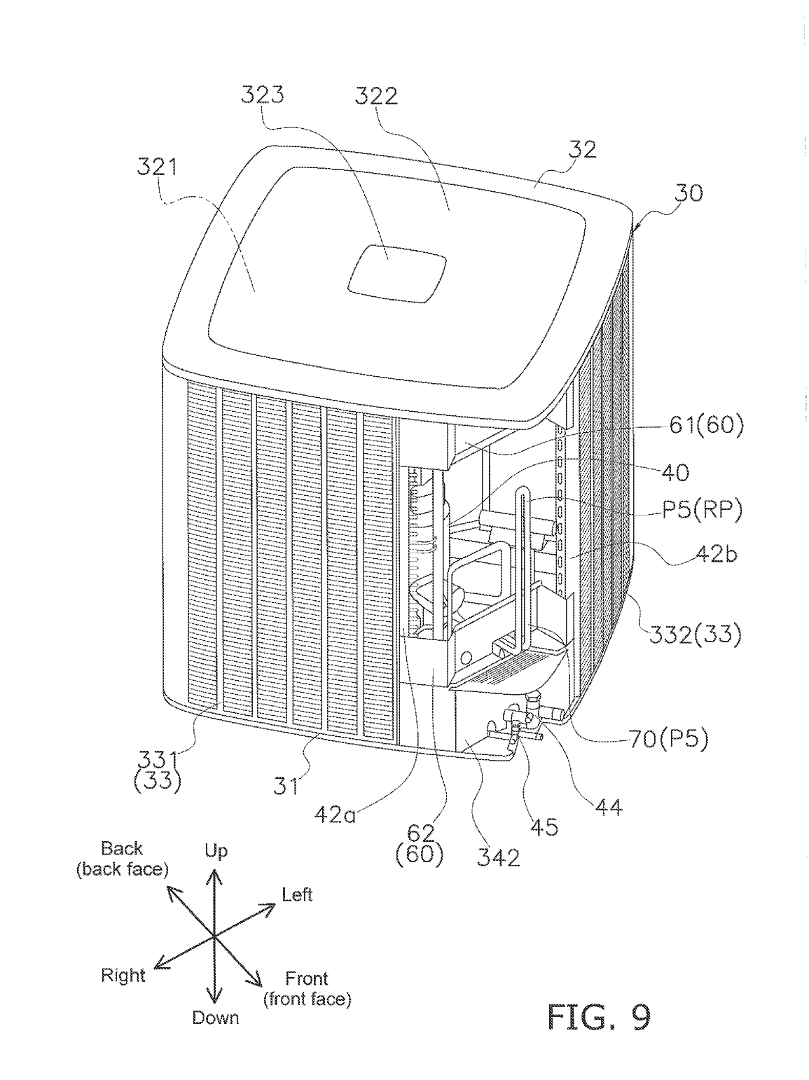

As illustrated in FIG. 4, the electrical components compartment SP2 is a space formed in the corner that is formed on the front face side among the four corners of the casing 30. In other words, the electrical components compartment SP2 is formed in the corner portion that is formed by the side face configured by the first side face grill 331 and the side face configured by the second side face grill 332. The electrical components compartment SP2 is surrounded by the corner cover 34, the partitioning plate 50, and the guard member 60. The substrate 47a on which the heat source unit controller 47 is mounted is placed in the electrical components compartment SP2. Furthermore, in the electrical components compartment SP2, the fifth refrigerant pipeline P5 extends from the machine compartment SP1 side in order to pass through the heat sink 49. The fifth refrigerant pipeline P5 has a vertical part 70 that extends in the up-and-down direction (vertical direction) in the electrical components compartment SP2. The vertical part 70 adjoins the partitioning plate 50. In the present embodiment, the vertical part 70 has a U-shaped curve that bends downward after extending upward in the electrical components compartment SP2 (refer to FIG. 6 and FIG. 9).

<Partitioning Plate 50>

FIG. 6 is an external perspective view of the heat source unit 20 in a state having removed the first corner cover 341. The heat source unit 20 has a partitioning plate 50 extending along the vertical direction inside the casing 30. As illustrated in FIG. 4, the partitioning plate 50 is placed between the end part of the first side face part 421 and the end part of the fourth side face part 424. In the heat source unit 20, as illustrated in FIG. 6, the partitioning plate 50 and the substrate 47a fixed to the partitioning plate 50 are exposed when the first corner cover 341 is removed.

The partitioning plate 50 includes a first plate 51 (equivalent to “first part” in the claims) and a second plate 52 (equivalent to “second part” in the claims). The first plate 51 and the second plate 52 can be divided.

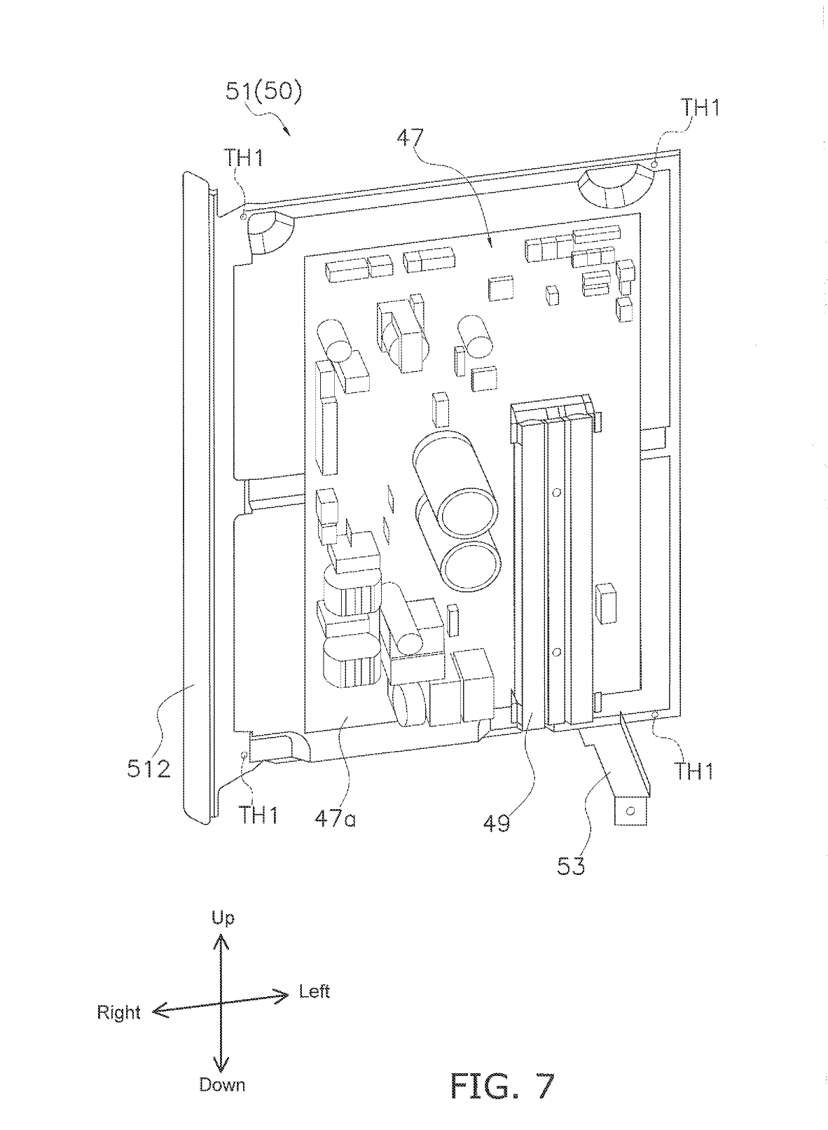

FIG. 7 is an external view of the first plate 51 in a state having the substrate 47a fixed. The first plate 51 is a roughly flat plate shaped member forming a part of a main face 50a of the partitioning plate 50. The first plate 51 has a roughly square shape from the front face view, and screw holes TH1 are formed near the four corners. The first plate 51 is screwed to the second plate 52 through the screw holes TH1. The substrate 47a on which the heat source unit controller 47 is mounted is fixed in the center portion of the first plate 51. A handle 53 that is used when placing the first plate 51 is provided near the lower end of the first plate 51. An insertion opening cover 512 that extends in the vertical direction is provided on the right end of the first plate 51. The insertion opening cover 512 is a portion covering an insertion opening 52b (to be described) formed on the second plate 52. The insertion opening cover 512 has a larger area than the insertion opening 52b.

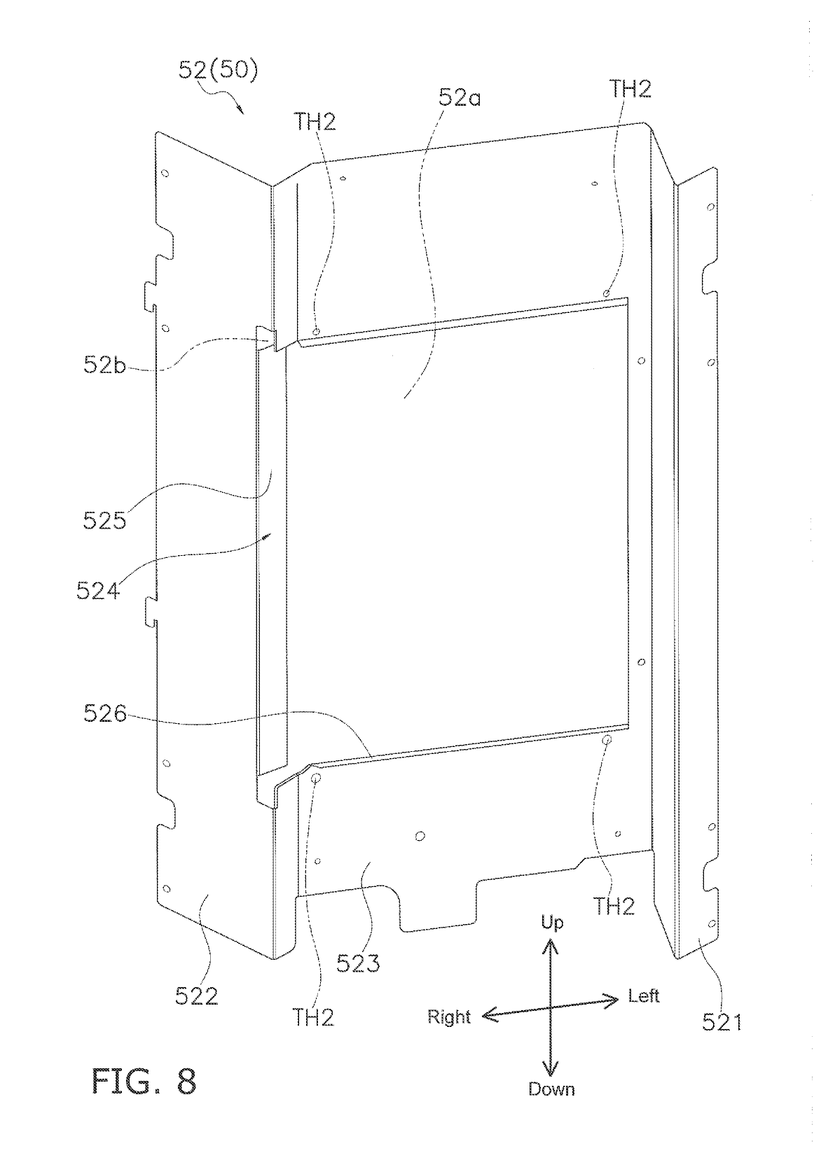

FIG. 8 is an external view of the second plate 52. The second plate 52 is a plate shaped member supporting the first plate 51. The second plate 52 is placed before the first plate 51 is placed. The second plate 52 has a larger contour than the first plate 51. The second plate 52 is fixed to a first tube plate 42a near the right end part, and is fixed to a second tube plate 42b near the left end part. After placement, the second plate 52 is fixed the first plate 51 that is inserted from the side (right direction) through the insertion opening 52b. The second plate 52 has a left side part 521, a right side part 522, and a middle part 523.

The left side part 521 is a portion forming the left end of the second plate 52, and is bent in a roughly L-shape in planar view. A plurality of screw holes are formed on the left side part 521, and the second plate 52 is screwed to the second tube plate 42b through the screw holes.

The right side part 522 is a plate-shaped portion forming the right end of the second plate 52. A plurality of screw holes are formed on the right side part 522, and the second plate 52 is screwed to the first tube plate 42a through the screw holes. The insertion opening 52b is formed on the left side end part of the right side part 522. The insertion opening 52b is an opening for inserting the first plate 51 in the second plate 52. A flange 524 is provided on the edge of the insertion opening 52b.

The flange 524 extends from the edge of the insertion opening 52b in essentially the same direction as the insertion direction (first direction dr1 described later) of the first plate 51. In other words, the angle formed by the direction in which the flange 524 extends and the first direction dr1 is 0° or more to 30° or less in planar view. The flange 524 has a flat part 525 facing the front face side. When the first plate 51 is inserted in the second plate 52, the flange 524 prevents the first plate 51 from rotating towards the machine compartment SP1 side (back face direction) because the flat part 525 contacts with the first plate 51.

The center part 523 is placed between the left side part 521 and the right side part 522, and is a plate shaped portion forming the center portion of the second plate 52. The middle part 523 forms the main face of the second plate 52. Furthermore, the front face of the middle part 523 forms the main face 50a of the partitioning plate 50 along with the first plate 51. A central opening 52a (equivalent to “first opening” in the claims) which is a large opening is formed in the middle part 523.

The central opening 52a forms a roughly square shape from the front face view. In the front face view, the central opening 52a is smaller than the surface area of the first plate 51. A circumferential edge part 526 is formed around the central opening 52a. As illustrated in FIG. 6, in a state of the partitioning plate 50 has been placed, the first plate 51 is exposed from the machine compartment SP1 side to the electrical components compartment SP2 side through the central opening 52a. Screw holes TH2 are formed near the four corners of the central opening 52a, and the first plate 51 is fixed by screws to the second plate 52 through the screw holes TH2. When the first plate 51 is fixed to the second plate 52, a part of the first plate 51 contacts the plate face of on the back face side (in other words, first space side) of the middle part 523.

The central opening 52a is formed to improve the working efficiency when placing the first plate 51. In other words, in the electrical components compartment SP2 of the heat source unit 20, as illustrated in FIG. 6, a vertical part 70 of the fifth refrigerant pipeline P5 extends in the vertical direction to pass through the heat sink 49, and the fifth refrigerant pipeline P5 may become an obstacle when moving the second plate 52 to the placement position. The central opening 52a is formed so as to prevent the second plate 52 from contacting the fifth refrigerant pipeline P5 when placing the second plate 52. Note that the placement method of the first plate 51 and the second plate 52 is described later.

<Guard Member 60>

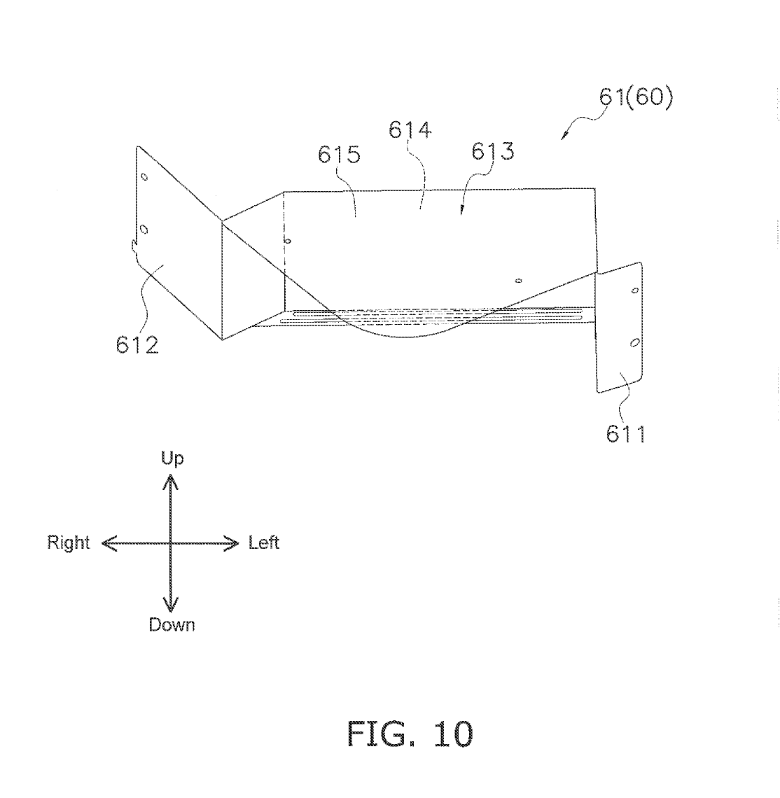

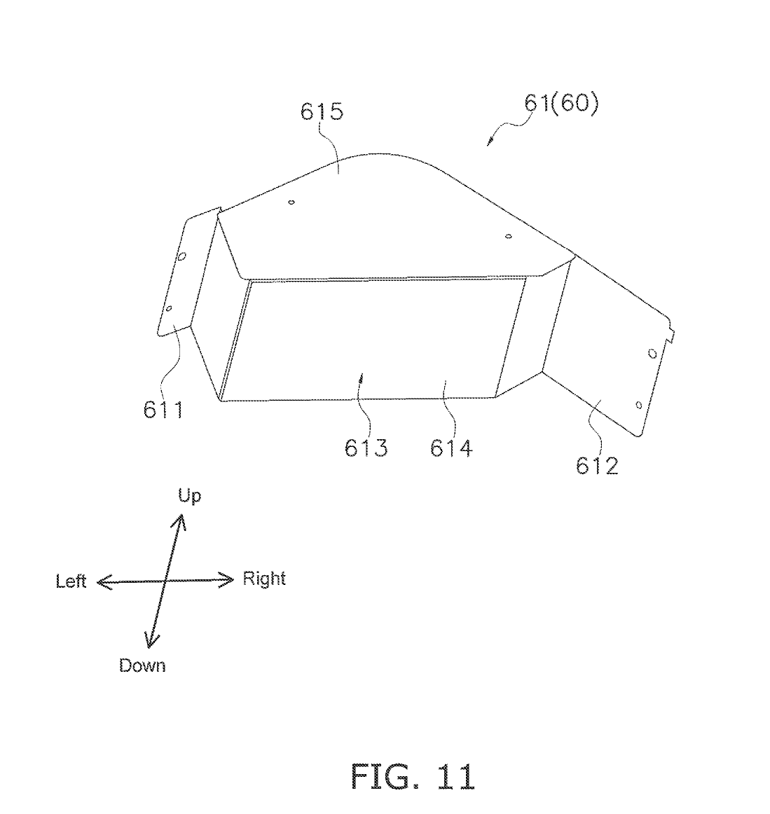

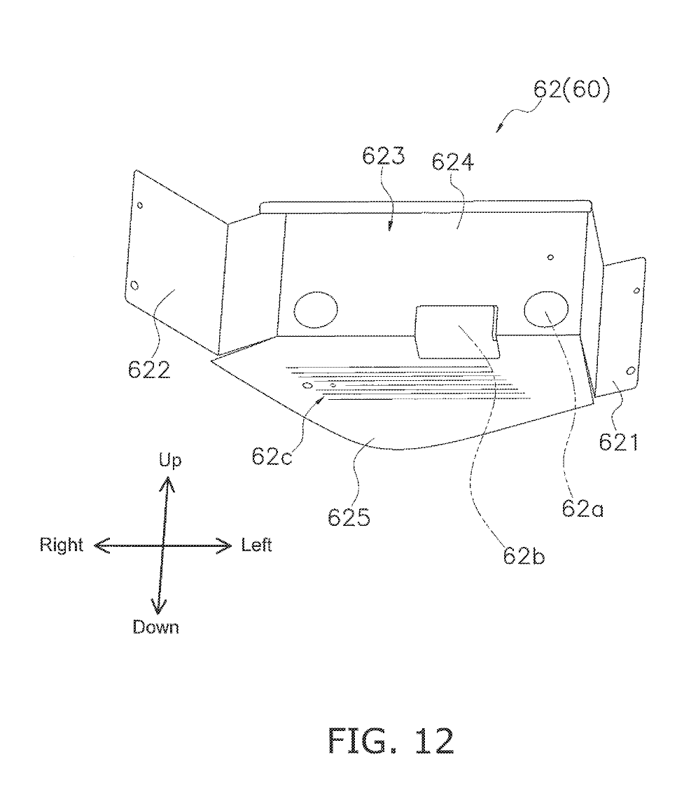

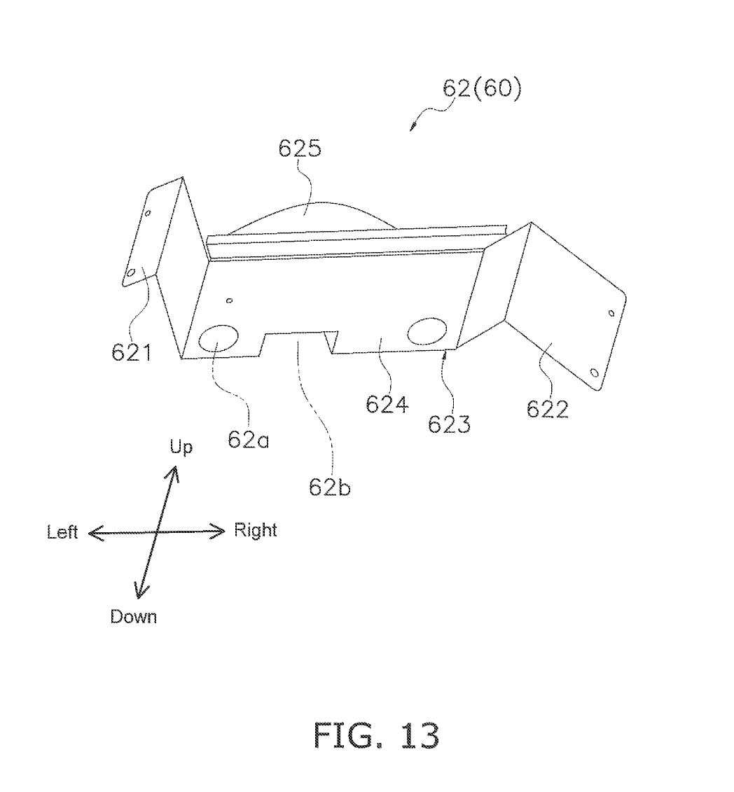

FIG. 9 is an external perspective view of the heat source unit 20 in a state having removed the partitioning plate 50 from the condition in FIG. 6. FIG. 10 is a front face perspective view of an upper guard member 61. FIG. 11 is a back face perspective view of an upper guard member 61. FIG. 12 is a front face perspective view of a lower guard member 62. FIG. 13 is a back face perspective view of a lower guard member 62.

The guard member 60 is a member for preventing liquids or the like from permeating into the electrical components compartment SP2 from above or below the partitioning plate 50. The guard member 60 is placed before the partitioning plate 50 is placed. Specifically, the guard member 60 includes an upper guard member 61 placed above the partitioning plate 50 and a lower guard member 62 placed below the partitioning plate 50.

The upper guard member 61 is a member for preventing liquids or the like from permeating into the electrical components compartment SP2 from above the partitioning plate 50. The upper guard member 61 is fixed by screws to the top plate 32 and the heat source-side heat exchanger 42. The upper guard member 61 includes a left upper part 611, a right upper part 612, and a middle upper part 613.

The left upper part 611 is a plate shaped portion forming the left end of the upper guard member 61. The left upper part 611 is screwed to the second tube plate 42b. The right upper part 612 is a plate shaped portion forming the right end of the upper guard member 61. The right upper part 612 is screwed to the first tube plate 42a. The middle upper part 613 is placed between the left upper part 611 and the right upper part 612. The middle upper part 613 and is a portion forming the middle portion of the upper guard member 61. The middle upper part. 613 has an upper back part 614 and a ceiling part 615 extending in the front face direction. The middle upper part 613 is screwed to the lower face side of the top plate 32 on the ceiling part 615.

The lower guard member 62 is a member for preventing liquids or the like from permeating into the electrical components compartment SP2 from below the partitioning plate 50. The lower guard member 62 is placed above the second corner cover 342. The lower guard member 62 is fixed by screws to the heat source-side heat exchanger 42. The lower guard member 62 includes a left lower part 621, a right lower part 622, and a middle lower part 623.

The left lower part 621 is a plate shaped portion forming the left end of the lower guard member 62. The left lower part 621 is screwed to the second tube plate 42b. The right lower part 622 is a plate shaped portion forming the right end of the lower guard member 62. The right lower part 622 is screwed to the first tube plate 42a.

The middle lower part 623 is placed between the left lower part 621 and the right lower part 622. The middle tower part 623 is a portion forming the middle portion of the lower guard member 62. The middle lower part 623 has a lower back part 624 and a bottom part 625 extending in the front face direction. A wiring opening 62a is formed on the lower back part 624. The wiring opening 62a is formed such that wiring that electrically connects the heat source unit blower motor 46a and the heat source unit controller 47 passes from the machine compartment SP1 side to the electrical components compartment SP2 side. A refrigerant pipeline opening 62b is formed from the lower back part 624 to the bottom part 625. The refrigerant pipeline opening 62b is formed such that the fifth refrigerant pipeline P5 passes from the machine compartment SP1 side to the electrical components compartment SP2 side. A plurality of slits 62c are formed on the bottom part 625. The slits 62c are formed such that air cooling the electrical components included in the heat source unit controller 47 brought from the outside into the electrical components compartment SP2 when the air-conditioning apparatus 100 is operating.

<Configuration of Heat Sink 49>

The heat sink 49 is provided on the substrate 47a. The fifth refrigerant pipeline P5 (vertical part 70) contacts with the heat sink 49. The heat sink 49 is an oblong member, and is placed to cover the heat-generating part 48 mounted on the substrate 47a from the front face. The heat sink 49 is thermal contact with the heat-generating part 48. Inside the heat sink 49, a space is formed along the longitudinal direction of the vertical part 70 of the fifth refrigerant pipeline P5, and a part of the vertical part 70 is stored in this space.

(3) Process for Manufacturing Heat Source Unit 20

The process of manufacturing the heat source unit 20 is described below. Note that in the following description, the face, that is formed by the front face portion of the first plate 51 exposed through the central opening 52a and the front face portion of the middle part 523 of the second plate 52, is defined as the main face 50a of the partitioning plate 50 in a placed state.

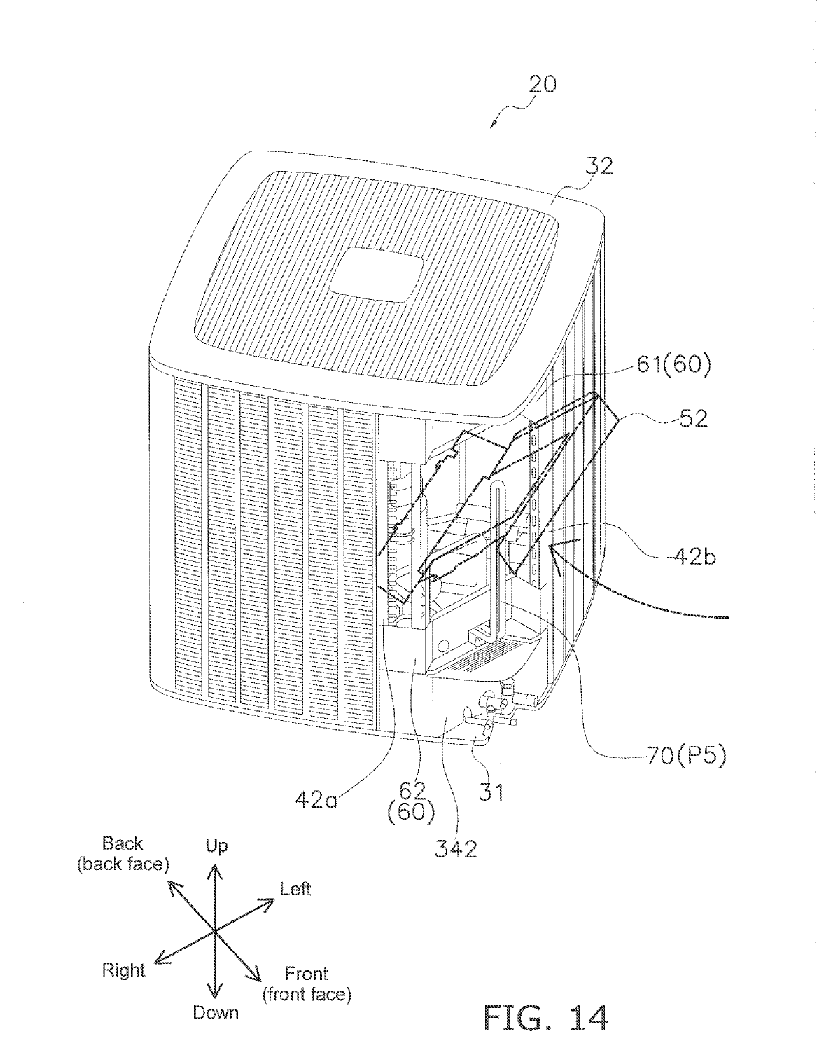

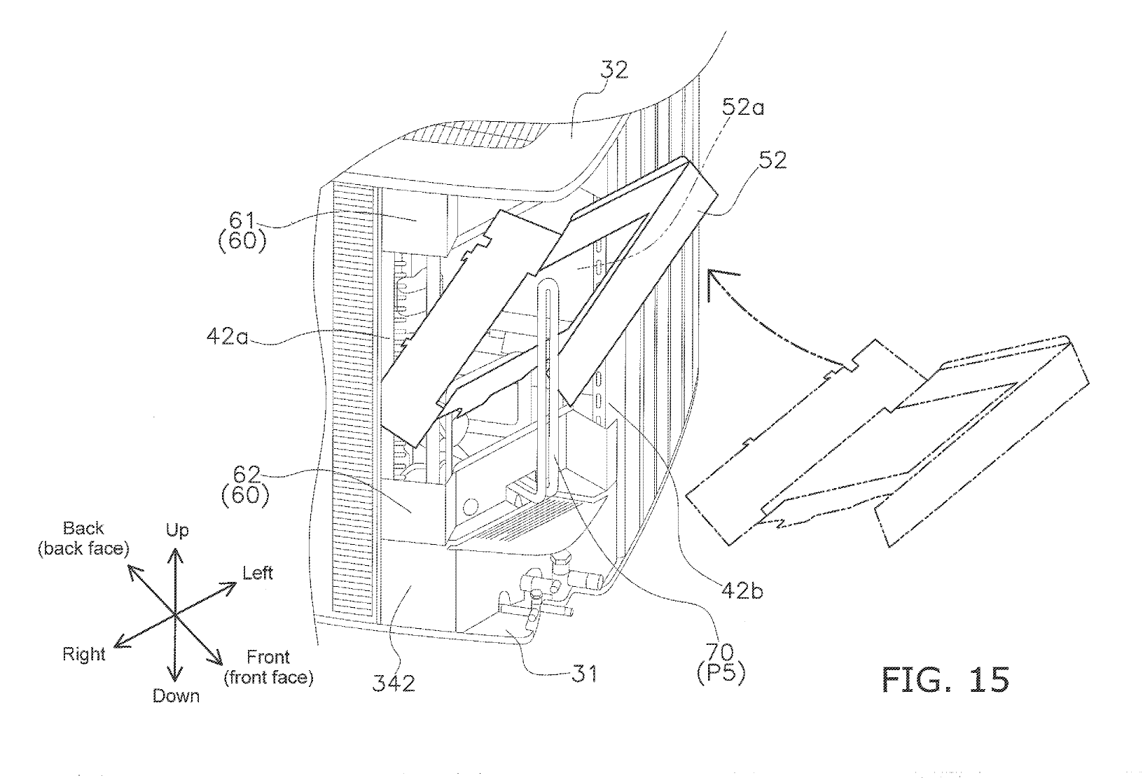

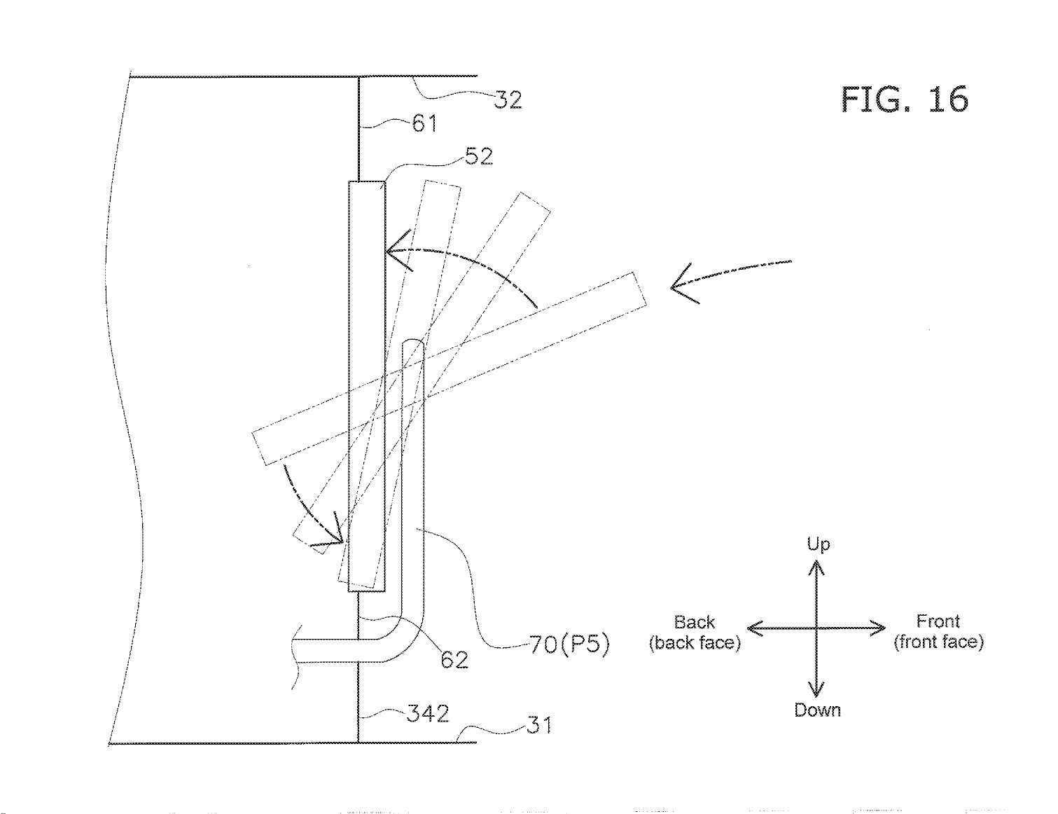

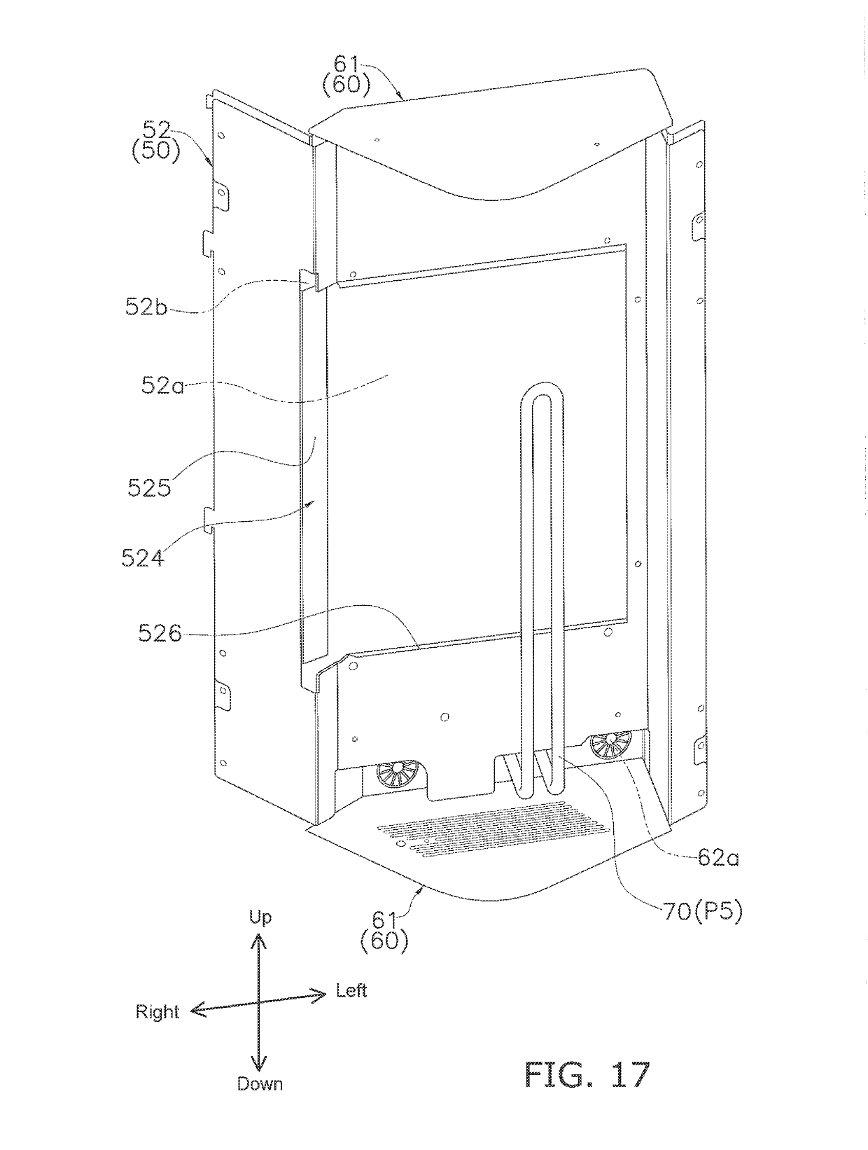

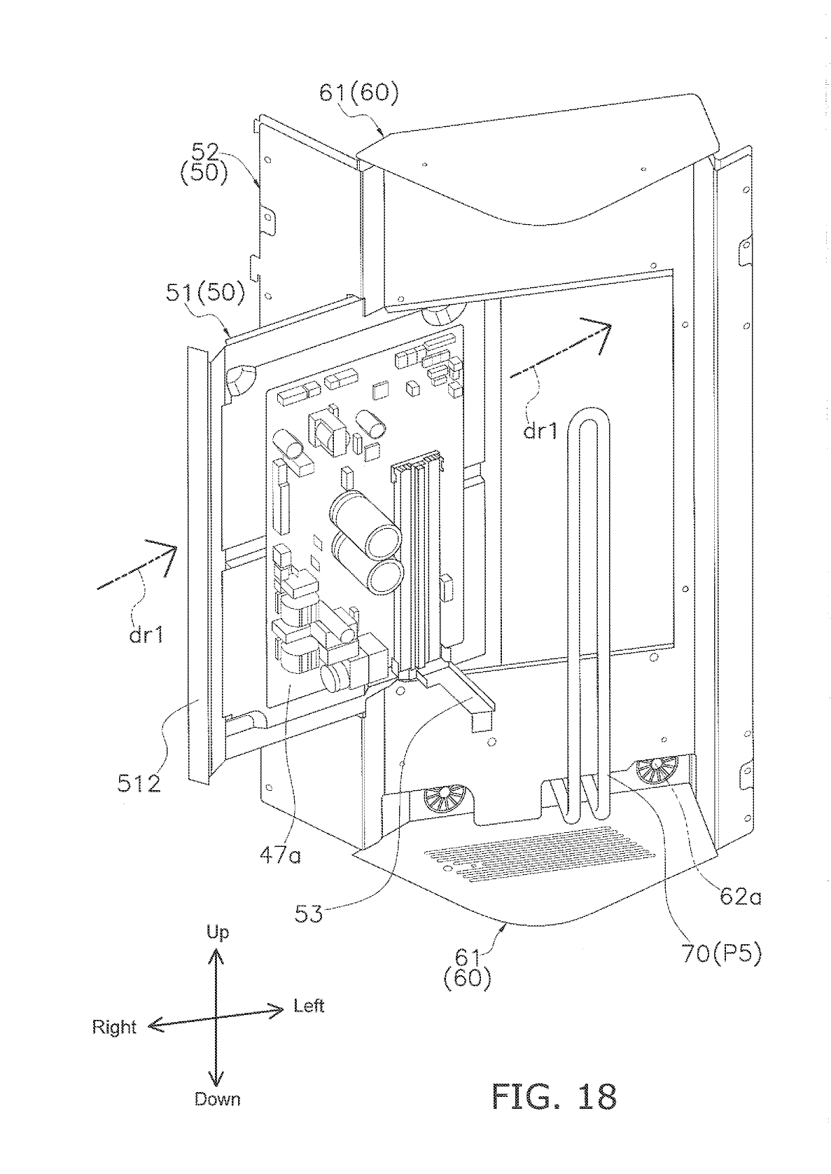

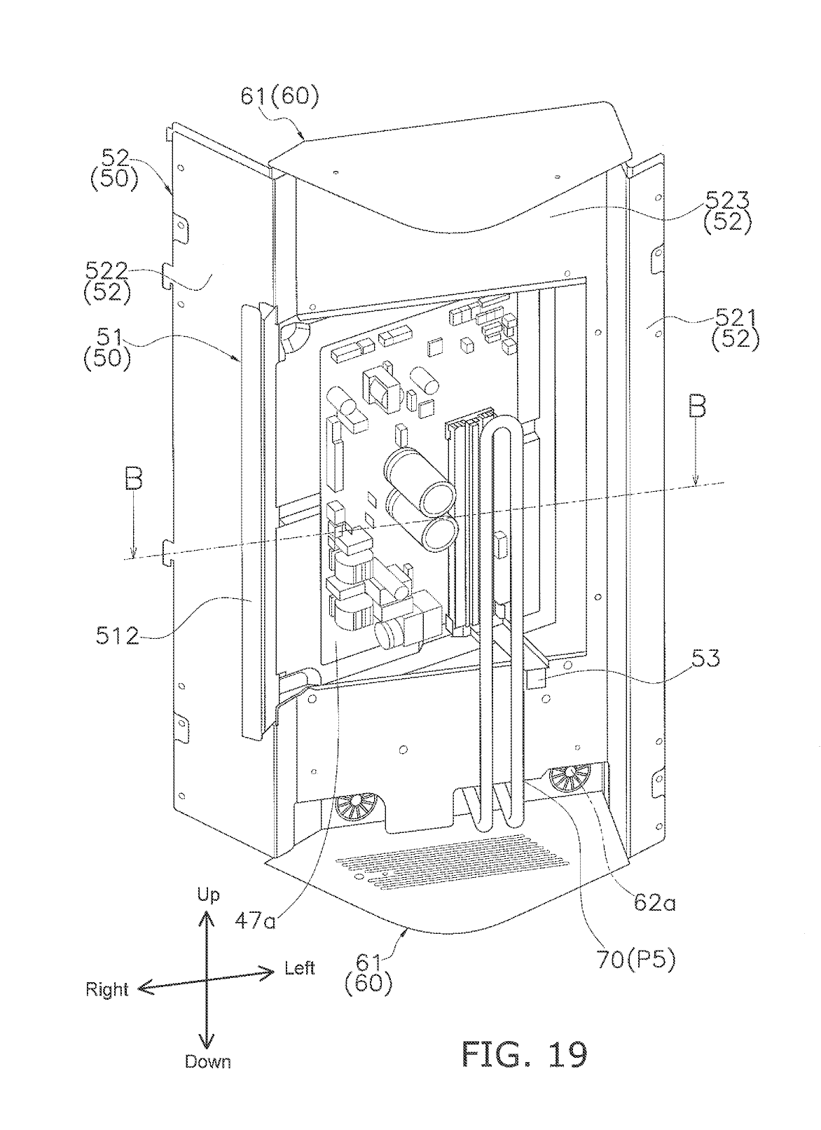

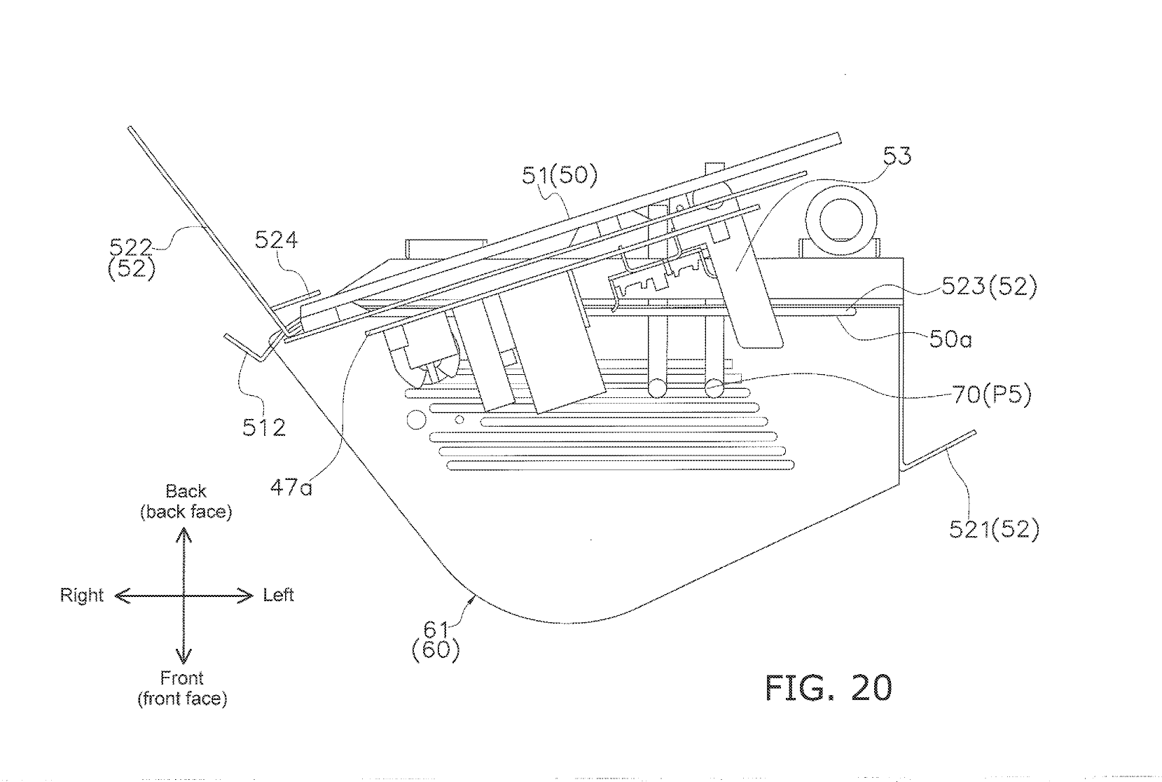

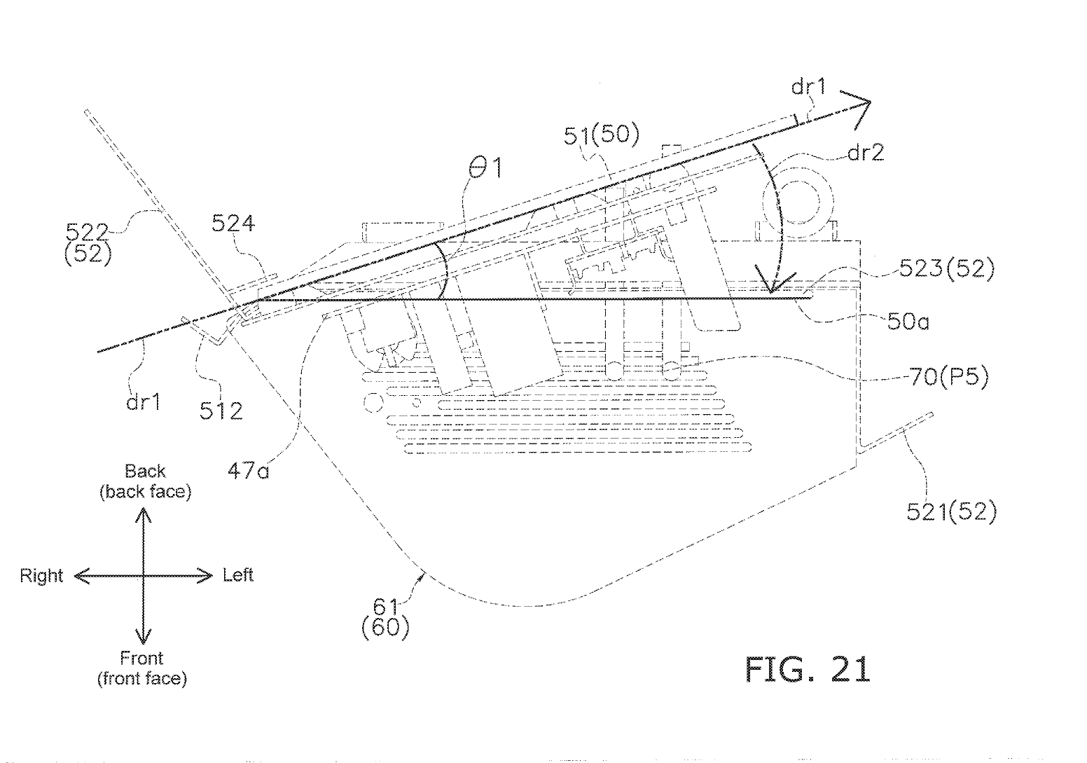

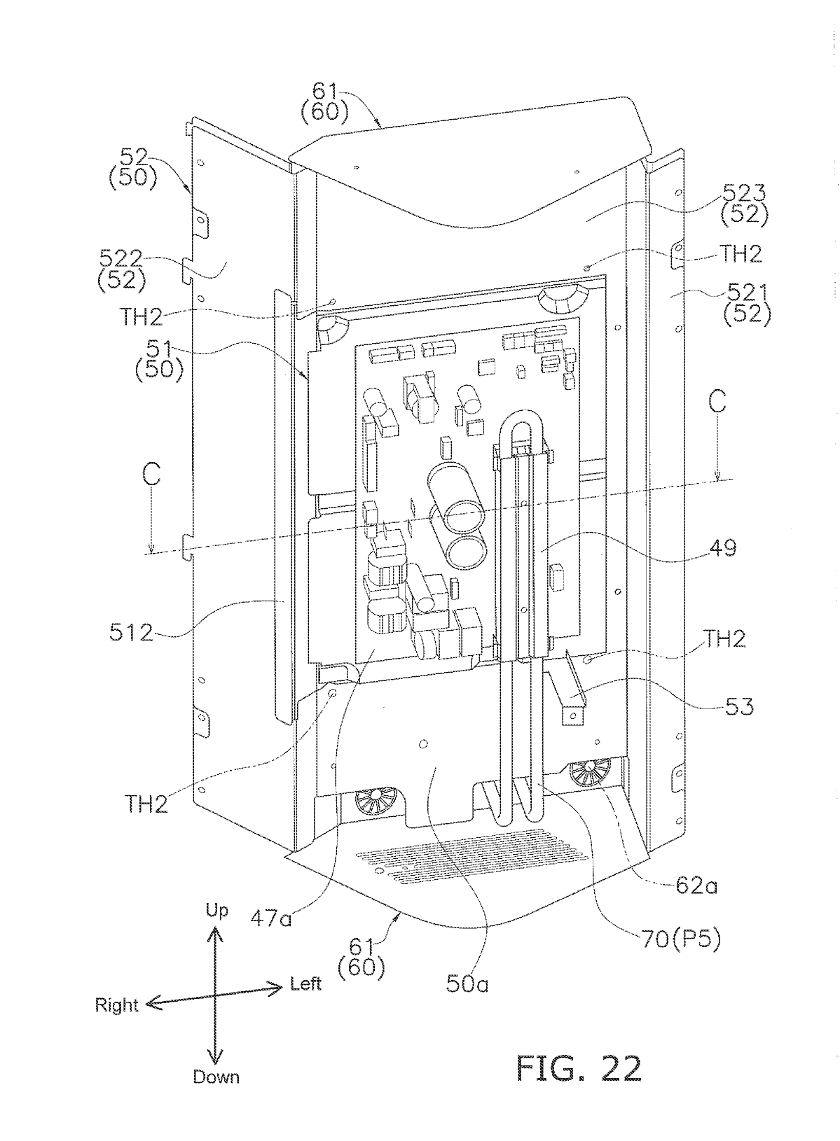

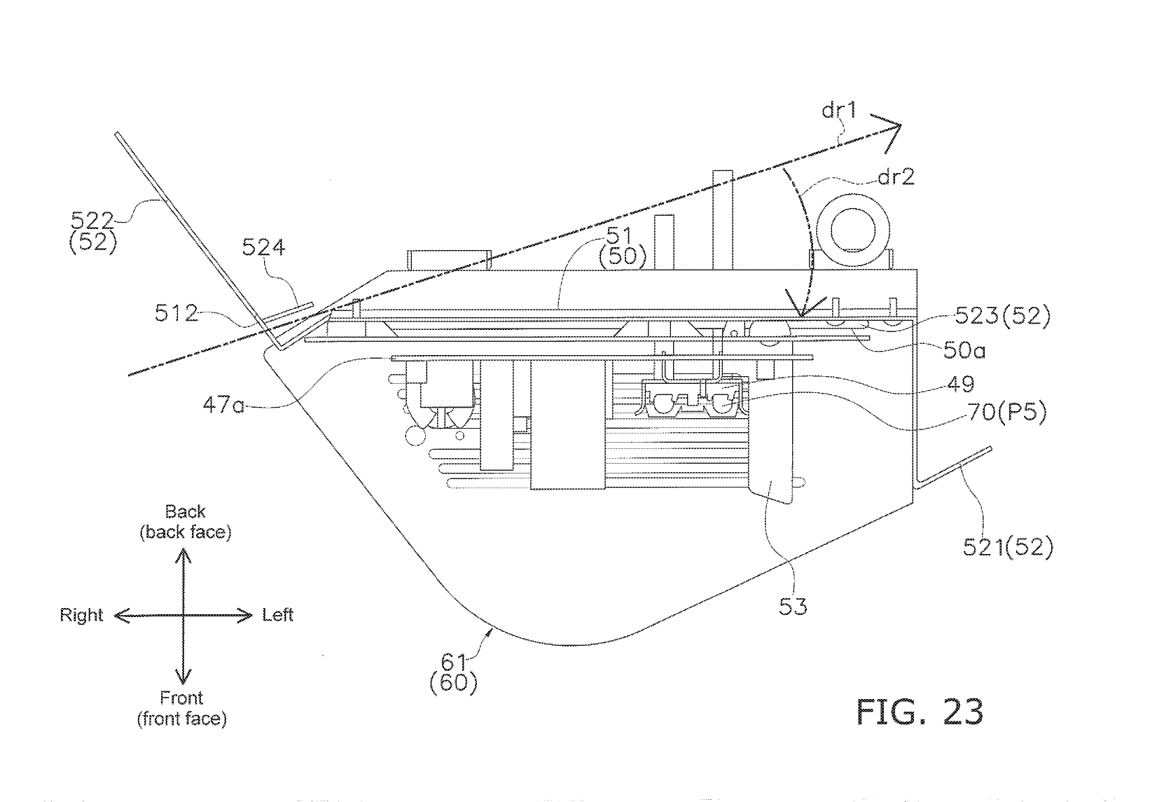

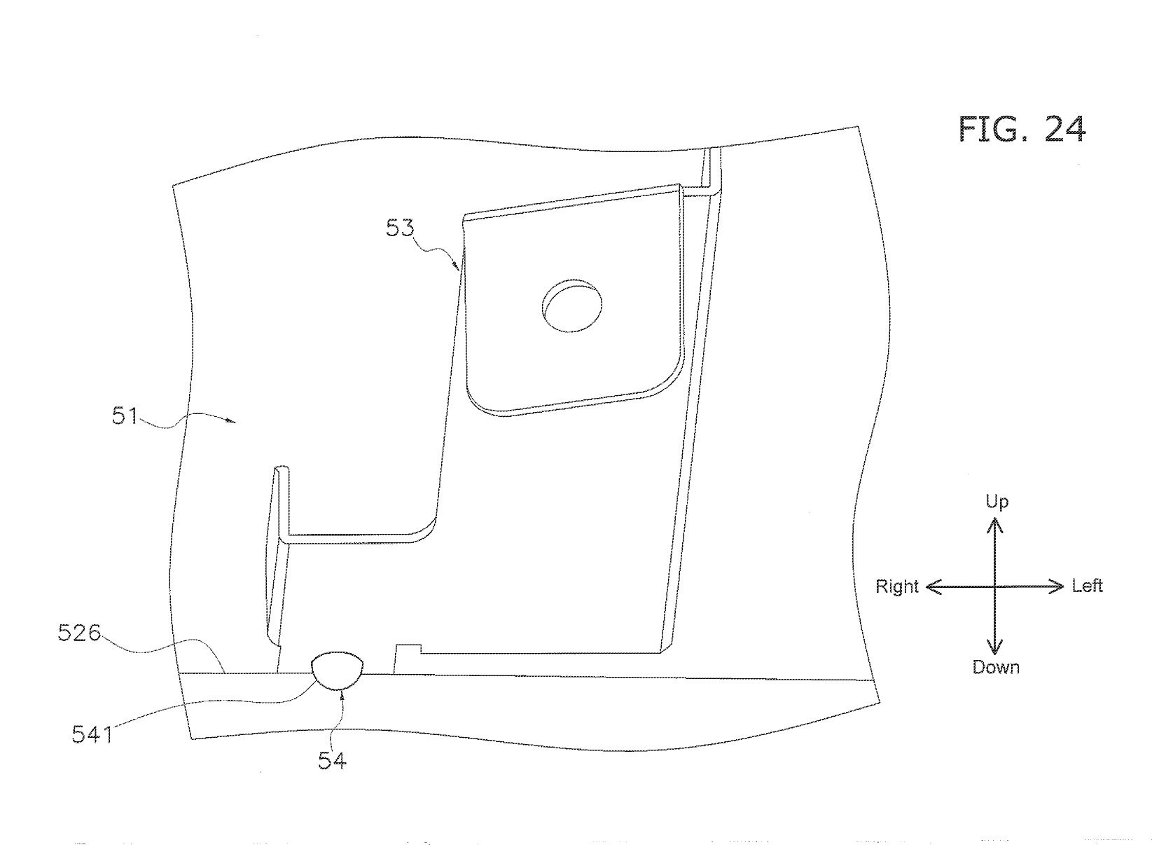

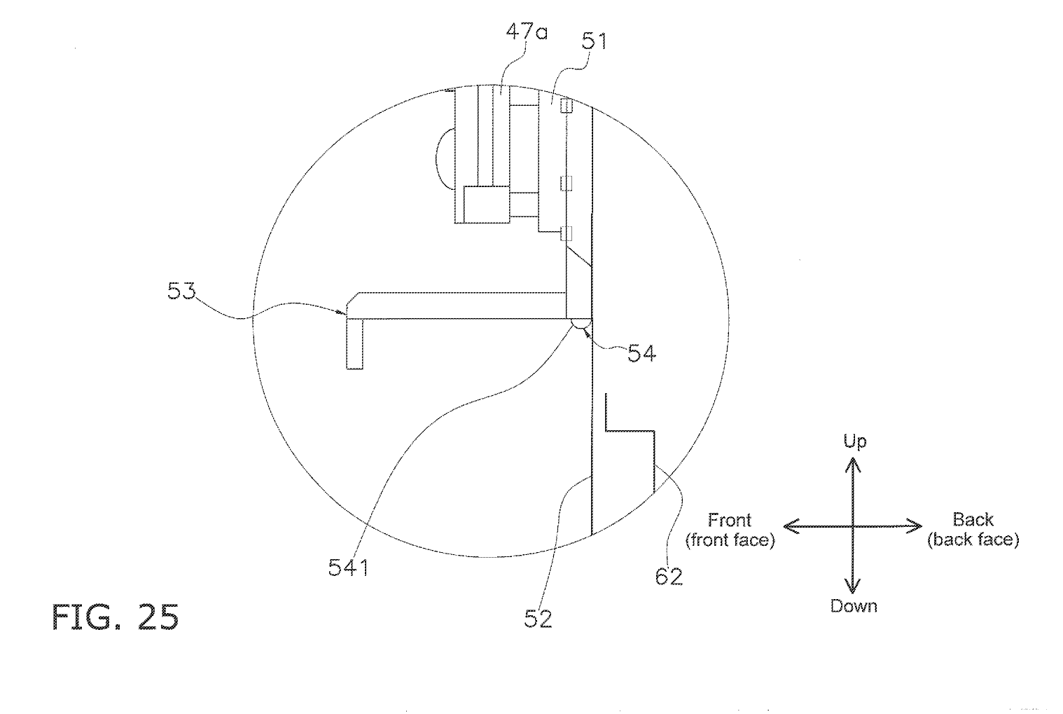

FIG. 14 is a diagram schematically illustrating an aspect of inserting the second plate 52 into the casing 30 in the state of FIG. 9. FIG. 15 is an enlarged view schematically illustrating an aspect of inserting the second plate 52 into the casing 30 in the state of FIG. 9. FIG. 16 is a right side face view schematically illustrating an aspect of moving the second plate 52 in a rotational manner to the placement position after inserting into the casing 30 in the state of FIG. 9. FIG. 17 is a front face view illustrating the second plate 52, the guard member 60, and the fifth refrigerant pipeline P5 in a placed condition. FIG. 18 is a diagram schematically illustrating a form of inserting the first plate 51 into the second plate 52 in the state of FIG. 17. FIG. 19 is a diagram schematically illustrating a form of further inserting the first plate 51 into the second plate 52 in the state of FIG. 18. FIG. 20 is a sectional view along B-B in FIG. 19. FIG. 21 is a schematic view highlighting and illustrating the first direction dr1 which is the insertion direction of the first plate 51, and the main face 50a in FIG. 20. FIG. 22 is a front face view illustrating the partitioning plate 50, the guard member 60, and the fifth refrigerant pipeline P5 in a placed condition. FIG. 23 is a sectional view along C-C in FIG. 22. FIG. 24 is a schematic view of the handle 53 as seen from the lower face in FIG. 22. FIG. 25 is a schematic view viewing the handle 53 from the left side face in FIG. 22.

When manufacturing the heat source unit 20, first, actuators such as the compressor 40 and four-way switching valve 41, and equipment such as the refrigerant pipeline RP are disposed in a predetermined position on the bottom plate 31. Next, the heat source-side heat exchanger 42 is placed on the bottom plate 31, and then the refrigerant pipeline RP is connected. Thereafter, the second corner cover 342 is placed on the bottom plate 31 such that the gas-side closing valve 44 and the liquid-side closing valve 45 are exposed.

Next, the guard member 60 is placed. At this time, the vertical part 70 is inserted into the refrigerant pipeline opening 62b, and the lower guard member 62 is moved to the placement position and then is fixed, such that the vertical part 70 of the fifth refrigerant pipeline P5 is exposed from the refrigerant pipeline opening 62b of the lower guard member 62. Thereafter, the top plate 32 on which the heat source unit blower motor 46a is fixed is placed after the side face grill 33 is placed on the bottom plate 31.

The reason for placing the top plate 32 before placing the partitioning plate 50 in this manner is because the installing of the wiring that connects the heat source unit blower motor 46a fixed to the top plate 32 and the heat source unit controller 47 must be performed before placing the partitioning plate 50. In other words, after placing the partitioning plate 50, the partitioning plate 50 becomes an obstacle, and thus installing the wiring connected to the heat source unit blower motor 46a in the front face side of the partitioning plate becomes difficult. Therefore, the partitioning plate 50 is placed after the top plate 32 is placed and routing of the wiring is finished.

Specifically, after placing the top plate 32, the wiring (not illustrated) connected to the heat source unit blower motor 46a passes through the wiring opening 62a of the lower guard member 62 and is secured on the front face side of the lower guard member 62. When the aforementioned process is completed, the heat source unit 20 is in the state illustrated in FIG. 9. In this condition, the partitioning plate 50 is placed. After the placement of the partitioning plate 50 is completed, each wiring including the wiring extending from the heat source unit blower motor 46a is connected to a predetermined terminal of the heat source unit controller 47. Thereafter, the first corner cover 341 is mounted after installation of a sealing material (not illustrated) or the like is performed.

<Placement of Partitioning Plate 50>

When the partitioning plate 50 is placed, the second plate 52 is placed before the first plate 51 is placed. As illustrated in FIG. 14 and FIG. 15, when the second plate 52 is placed, the second plate 52 is inserted between the bottom plate 31 and top plate 32 (in other words, inside the casing 30) from the front face side (more specifically above the front face side) with regard to the main face 50a while inclining the second plate 52 to the front face side. When the second plate 52 is inserted, the vertical part 70 of the fifth refrigerant pipeline P5 may be an obstacle, but contact between the second plate 52 and the vertical part 70 can be prevented by the vertical part 70 passing through central opening 52a. In this aspect, the second plate 52 is inserted to the back face side. Furthermore, when insertion of the second plate 52 to a fixed location is completed to a specific level, the second plate 52 is moved to the placement position while raising to the back face side until in the position of placed state, as shown in FIG. 16. In other words, After the second plate 52 is inserted between the bottom plate 31 and the top plate 32, the second plate 52 is moved to the placement position by rotating on a horizontal axis in a state where the second plate 52 (partitioning plate 50) is in place, and then is fixed.

When placement of the second plate 52 is completed, the first plate 51 is placed. Note that before the first plate 51 is placed, the substrate 47a on which the heat source unit controller 47 is mounted is fixed to the first plate 51. As illustrated in FIG. 18 through FIG. 20, when the first plate 51 is placed, first, the insertion opening cover 512 of the first plate 51 is grasped, and the first plate 51 is inserted in the insertion opening 52b of the second plate 52 from the right direction (lateral) in the direction along the main face 50a At this time, the first plate 51 is inserted slightly tilted with regard to the main face 50a as illustrated in FIG. 21. In the following description, the direction in which the first plate 51 is inserted is referred to as first direction dr1 (see FIG. 18 and FIG. 21).

As illustrated in FIG. 21, the first plate 51 is inserted tilted with regard to the main face 50a such that angle θ1 is formed between the first direction dr1 and the main face 50a in planar view. The angle θ1 is assumed to be 30° or less. In the present embodiment, the flange 524 extends in nearly the same direction as the first direction dr1 from the edge of the insertion opening 52b, and in the step of inserting the first plate 51, the angle θ1 exceeding 30° can be prevented due to the flat part 525 of the flange 524 contacting the back face of the first plate 511. In other words, the first direction dr1 can also be referred to as the direction along the main face 50a.

The reason that the first plate 51 is inserted being inclined with regard to the main face 50a is as described below. In other words, if the first plate 51 is inserted in the direction where the main face 50a extends from the insertion opening 52b (in other words, straight in the left direction), there is concern that the various electrical components mounted on the substrate 47a might contact the vertical part 70 of the fifth refrigerant pipeline P5. In order to avoid this situation, the first plate 51 is inserted in the second plate 52, tilted with regard to the main face 50a in the manner described above.

When insertion of the first plate 51 is completed, the handle 53 is grasped, and the first plate 51 is rotated in the second direction dr2 (front face direction, see FIG. 21 and FIG. 23), moved to the placement position, and then is fixed. In other words, After the first plate 51 is inserted between the bottom plate 31 and the top plate 32 from the side with regard to the main face 50a, the first plate 51 is moved to the placement position by rotating around the vertical axis in the state where the first plate 51 (partitioning plate 50) is in place and fixed.

Herein, the handle 53 has a protrusion 54 on the base surface side. The protrusion 54 is positioned at a height at which contact is made with the circumferential edge part 526 of the central opening 52a when the first plate 51 is rotated and moved in the second direction dr2. Therefore, the protrusion 54 can be an element that contacts the circumferential edge part 526 and restricts the rotation of the first plate 51 in the step that the first plate 51 is rotated and moved in the second direction dr2. However, as illustrated in FIG. 24 and FIG. 25, a curved surface 541 that can slide on the circumferential edge part 526 is formed on the protrusion 54, and the curved surface 541 contacts the circumferential edge part 526. Therefore, when the protrusion 54 contacts the circumferential edge part 526 in the step of rotating the first plate 51 in the second direction dr2, the protrusion 54 can slide and ride over the circumferential edge part 526 because a force that causes rotational movement is continuously applied. As a result, the first plate 51 is moved to the placement position.

The first plate 51 is screwed to the second plate 52 through the screw holes TH1 when moved to the placement position. In other words, the first plate 51 contacts the back surface (surface on the machine compartment SP1 side) of the second plate 52 in the vicinity of the screw holes TH1. In other words, the first plate 51 is fixed to the plate surface of the second plate 52 on the machine compartment SP1 side.

Herein, the operation of screwing the first plate 51 in the placement position can be smoothly performed. Because the protrusion 54 contacts the circumferential edge part 526 and restricts movement of the first plate 51, even if the first plate 51 appears to be rotated to the back surface direction by applying a force to the first plate 51 from the front surface side.

(4) Characteristics of Heat Source Unit 20

The heat source unit 20 of the present embodiment has characteristics such as the following.

<A>

As mentioned above, the heat source unit 20 of the air-conditioning apparatus 100 comprises the heat source-side heat exchanger 42, the actuators such as the compressor 40, the heat source unit controller 47 including various electrical components, the casing 30, and the partitioning plate 50. The heat source unit controller 47 controls driving of the actuators. The casing 30 houses the heat source-side heat exchanger 42, the actuators, and the heat source unit controller 47. The partitioning plate 50 is placed inside the casing 30. The casing 30 has a bottom plate 31 and a top plate 32. A vent 321 for venting air upward is formed on the top plate 32. The heat source-side heat exchanger 42 has the first side face part 421, the second side face part 422, the third side face part 423, and the fourth side face part 424. The second side face part 422 adjoins the first side face part 421. The third side face part 423 is opposite the first side face part 421 and adjoins the second side face part 422. The fourth side face part 424 is opposite the second side face part 422 and adjoins the third side face part 423. The first side face part 421 faces the side face configured by the first side face grill 331 (that is, one side face of the casing 30). The fourth side face part 424 faces the side face configured by the second side face grill 332 (that is, one side face of the casing 30). The end part of the first side face part 421 (that is, the first tube plate 42a) configures one end of the heat source-side heat exchanger 42. The end part of the fourth side face part 424 (that is, the second tube plate 42b) configures the other end of the heat source-side heat exchanger 42. The actuators are placed on a machine compartment SP1. The machine compartment SP1 is a space surrounded by the first side face part 421, the second side face part 422, the third side face part 423, the fourth side face part 424, and the partitioning plate 50. The heat source unit controller 47 is disposed in an electrical components compartment SP2. The electrical components compartment SP2 is a space partitioned from the machine compartment SP1 by the partitioning plate 50. The electrical components compartment SP2 is positioned in the corner formed by the side face configured by the first side face grill 331 and the side face configured by the second side face grill 332. The partitioning plate 50 is positioned between the end portion of the first side face part 421 and the end portion of the fourth side face part 424. When placed, the partitioning plate 50 is fixed after at least one part of the partitioning plate 50 is inserted between the bottom plate 31 and the top plate 32 from the side with regard to the main face 50a of the partitioning plate 50 in a placed state.

The heat source unit 20 is thereby configured so that even in the event that the partitioning plate 50 is placed after the bottom plate 31 and the top plate 32 has been placed, the partitioning plate 50 can still be placed easily. That is, the placing of the partitioning plate 50 is easy, and the heat source unit 20 is configured so that the work efficiency related to the manufacturing of the heat source unit 20 improves.

<B>

As mentioned above, the partitioning plate 50 includes the first plate 51. The first plate 51 is a flat member. The first plate 51 is inserted in the first direction dr1 along the main face 50a of the partitioning plate 50 in a placed state. The heat source unit 20 is thereby is configured so that placement of the partitioning plate 50 is easy with a simple configuration.

Also, as mentioned above, when the first plate 51 is inserted, the first plate 51 is inclined with regard to the main face 50a of the partitioning plate 50 in a placed state. After inserting, the first plate 51 is moved to the placement position by rotating around the vertical axis in the state of placement.

The heat source unit 20 is thereby configured so that placing the partitioning plate 50 is easy with a simple configuration.

Furthermore, as mentioned above, the first plate 51 has the handle 53. The handle 53 is used for the rotation of the first plate 51 after the first plate 51 is inserted.

Thereby, in the heat source unit 20, the first plate 51 can easily be rotate to the placement position after inserting.

<C>

As mentioned above, the partitioning plate 50 includes the second plate 52. The second plate 52 is a member that supports the first plate 51. The outline of second plate 52 is bigger than that of the first plate 51. The second plate 52 is placed before the first plate 51 is placed. When placing, the second plate 52 is inserted between the bottom plate 31 and the top plate 32 from the front side with regard to the main face 50a of the partitioning plate 50 in a placed state. After the second plate 52 is inserted between the bottom plate 31 and the top plate 32, the second plate 52 is rotated around the horizontal axis in the condition of placement. By rotating around the condition of placement of the horizontal axis, the second plate 52 moves to the placement position, and then, is fixed. That is, the partitioning plate 50 has a partitioned structure that divides into the first plate 51 and the second plate 52, and the first plate 51 and the second plate 52 are placed

Thereby, placing the partitioning plate 50 in the heat source unit 20 is easy.

Also, as mentioned above, the insertion opening 52b is formed in the second plate 52 so that the first plate 51 can be inserted. The first plate 51 is inserted to the second plate 52 by way of the insertion opening 52b. After the first plate 51 is inserted to the second plate 52, the first plate 51 is fixed to the second plate 52.

Thereby, placing the partitioning plate 50 in the heat source unit 20 is easy.

Furthermore, as mentioned above, the central opening 52a is formed in the main face of the second plate 52. The central opening 52a is equal to or smaller than the area of the main face of the first plate 51 in the front view. The first plate 51 is fixed to the plate surface on the machine compartment SP1 side of the second plate 52. The first plate 51 is exposed from the machine compartment SP1 side to the electrical components compartment SP2 side by way of the central opening 52a. The handle 53 has a protrusion 54. The protrusion 54 is positioned to a height that comes into contact with the circumferential edge part 526 of the central opening 52a when the first plate 51 is moved by rotation. The protrusion 54 has a curved surface 541 that has a shape that slides off the circumferential edge part 526 of the central opening 52a.

Thereby, when the first plate 51 is fixed, the protrusion 54 comes into contact with circumferential edge part 526, and the first plate 51 is harder to be moved by rotation from the placement position to the backside.

<D>

As mentioned above, the fifth refrigerant pipeline P5 is disposed in the electrical components compartment SP2. The fifth refrigerant pipeline P5 adjoins the partitioning plate 50.

Thus, even in a situation where a structure like the fifth refrigerant pipeline P5 that can become an obstacle to the placement work exists, the heat source unit 20 is configured so that the partitioning plate 50 can be placed easily.

Also, as mentioned above, the heat source unit controller 47 is implemented in the substrate 47a. The substrate 47a is fixed to the first plate 51 (that is, a portion of the partitioning plate 50). The substrate 47a has the heat sink 49. The heat sink 49 is in contact with the fifth refrigerant pipeline P5.

Furthermore, as mentioned above, the fifth refrigerant pipeline P5 includes the vertical part 70 that extends along a vertical direction.

(5) Modified Examples

<A>

In the aforementioned embodiment, when placing the first plate 51, the first plate 51 is configured to be inserted from the right side with regard to the main face 50a. However, the first plate 51 is not limited to this, and can be configured to be inserted from the left side with regard to the main thee 50a, In such case, in the second plate 52, the insertion opening 52b is formed on the left side part 521 and not the right side part 522.

<B>

In the aforementioned embodiment, when placing the first plate 51, the first plate 51 is inserted being inclined with regard to the main face 50a. However, when the first plate 51 is inserted, the first plate 51 does not necessarily have to be inclined with regard to the main face 50a. That is, when placing the first plate 51, the first plate 51 is configured to be inserted in the same direction with regard to the main face 50a (the direction that is parallel to the direction that the main face 50a extends), In such case, regarding the planar view, angle 01 is not formed between the direction that the first plate 51 is inserted and the main face 50a (that is, the angle θ1 is 0°).

<C>

In the aforementioned embodiment, when placing the second plate 52, the second plate 52 is configured to be inserted from the front side with regard to the main face 50a. However, the second plate 52 is not limited to this, and can be configured with regard to the main face 50a to be inserted from the side. In such case, regarding the second plate 52, the central opening 52a does not necessarily have to be formed.

<D>

In the aforementioned embodiment, the heat source unit 20 has the partitioning plate 50 inside the casing 30. However, the heat source unit 20 is not limited to this, and a partitioning plate 80 can be placed instead of the partitioning plate 50. The description regarding the partitioning plate 80 is the following.

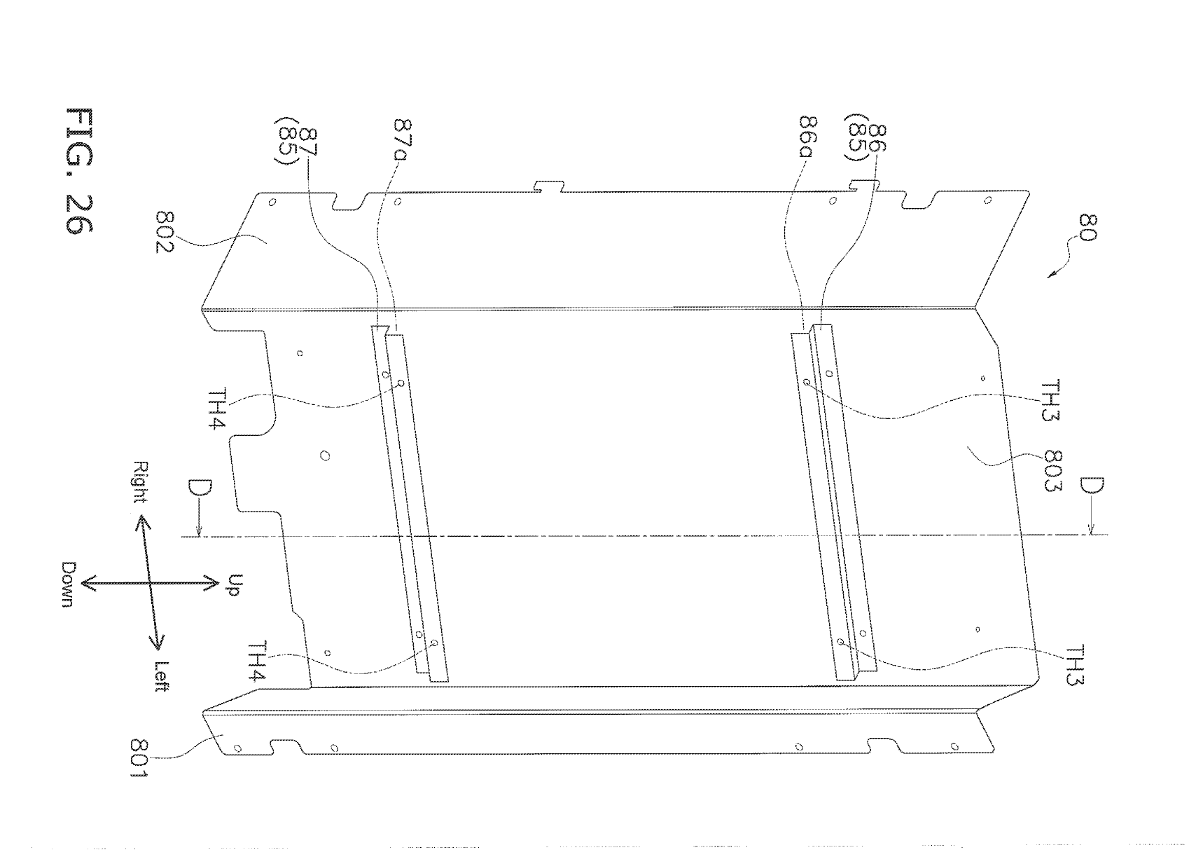

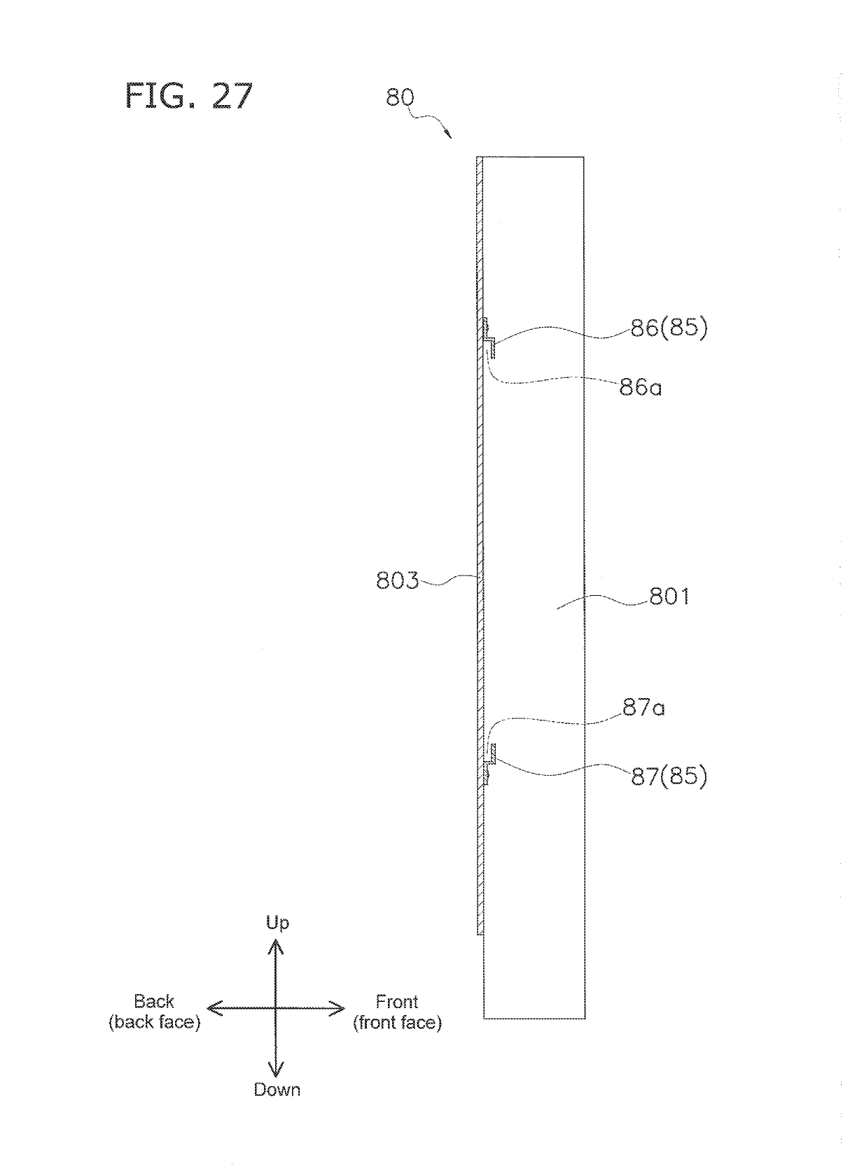

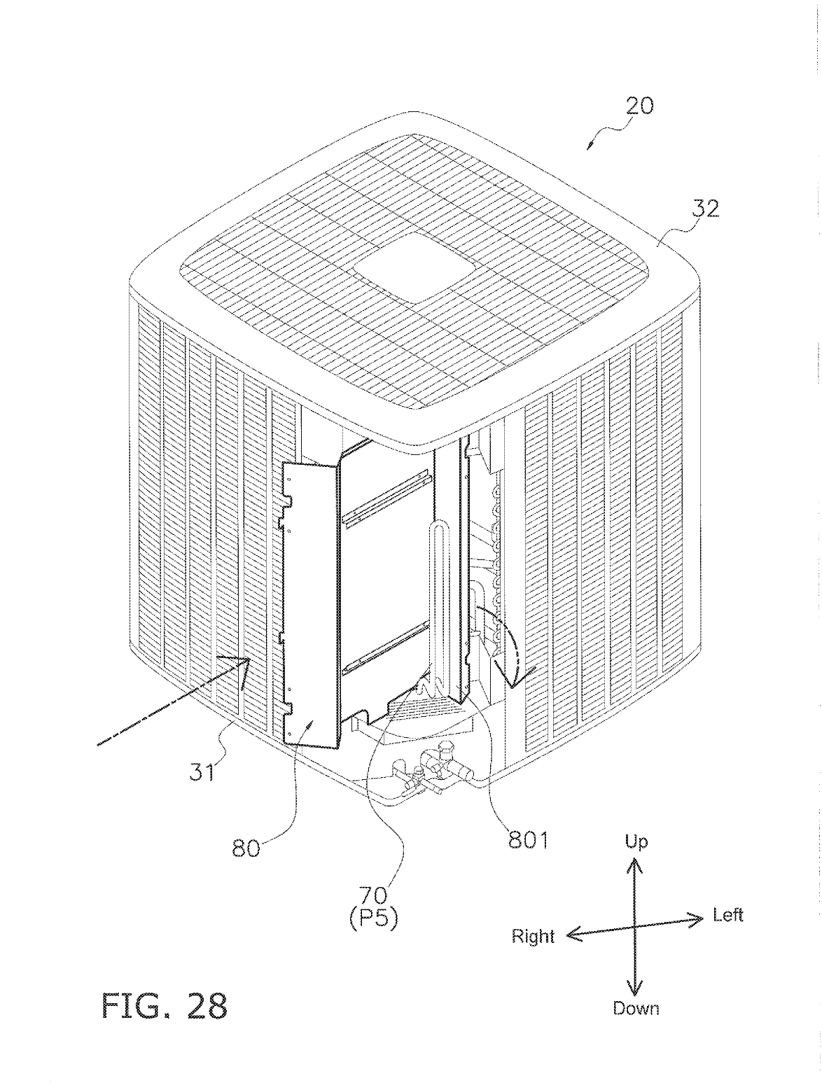

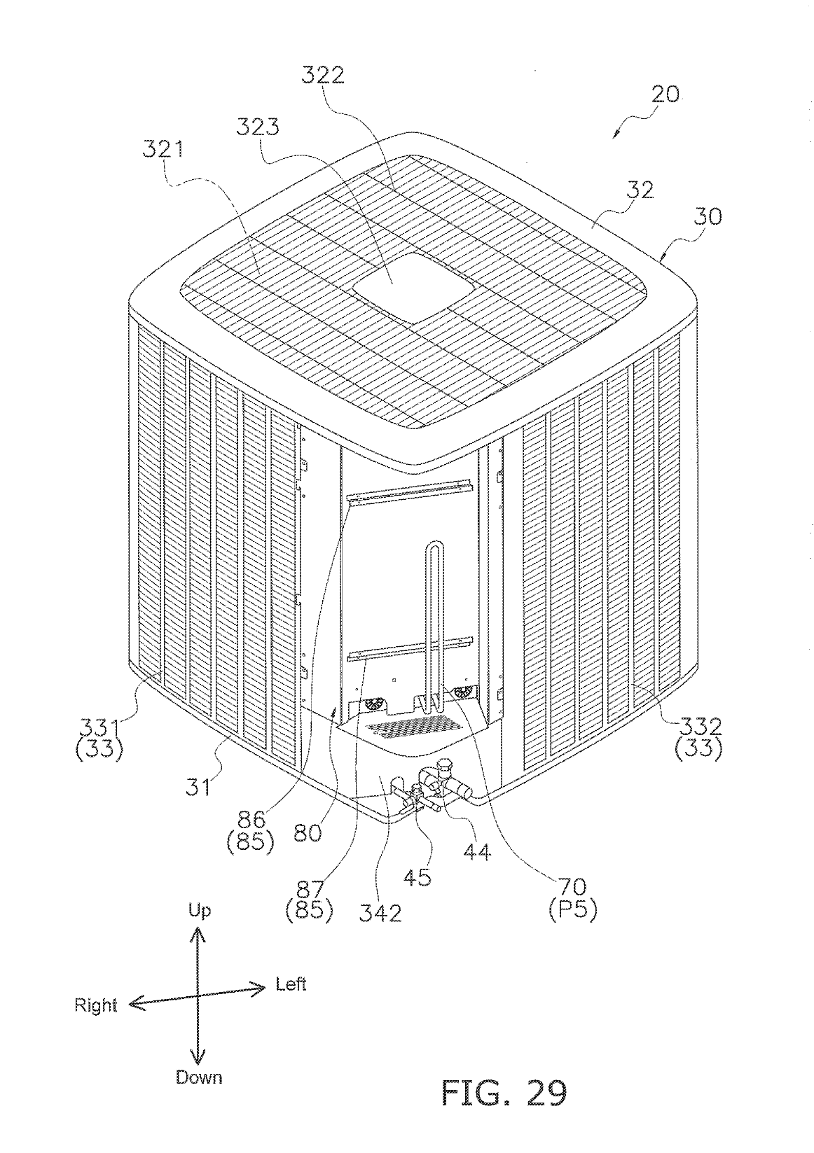

FIG. 26 is an external view of the partitioning plate 80. FIG. 27 is a sectional view along D-D in FIG, 26. Regarding the condition shown in FIG. 9, FIG. 28 is a diagram schematically illustrating a form of inserting the partitioning plate 80 into the casing 30 in the condition illustrated in FIG. 9. FIG. 29 is a diagram showing the condition of placing the partitioning plate 80 inside the casing 30 in the condition shown in FIG. 9.

In the same way as the partitioning plate 50, the partitioning plate 80 is placed between the end part of the first side face part 421 and the end part of the fourth side face part 424. The partitioning plate 80 is fixed to the first tube plate 42a near the right end thereof, and is fixed to the second tube plate 42b near the left end thereof. The partitioning plate 80 does not have a structure like the partitioning plate 50 of dividing into the first plate 51 and the second plate 52. Specifically, the partitioning plate 80 has a left side part 801, a right side part 802, and a center part 803.

The left side part 801 is a part that configures the left end of the partitioning plate 80, and in the planar view, is bent substantially to an L-shape. A plurality of screw holes is formed on the left side part 801, and the left side part 801 is fixed onto the second tube plate 42b through screw holes. The right side part 802 is a plate-form part that configures the right end of the partitioning plate 80. A plurality of screw holes is formed on the right side part 802, and the right side part 802 is fixed onto the first tube plate 42a through screw holes.

The center part 803 is positioned between the left side part 801 and the right side part 802, and is a plate-form part that configures the center part of the partitioning plate 80. The center part 803 configures the main face of the partitioning plate 80. A substrate fixing part 85 is placed in the center part 803 to fix the substrate 47a. The substrate fixing part 85 mainly includes an upper fixing part 86 and a lower fixing part 87.

The upper fixing part 86 is a plate-form. member that is bent stepwise in the side view. The upper fixing part 86 is fixed onto the top portion of the center part 803 by screws. A plurality of the screw holes TH3 that is formed on the upper fixing part 86. Through the screw holes TH3 the upper fixing part 86 is fixed onto the section near the upper end of the substrate retaining member 90 (to be described). A first clearance 86a is formed in between a portion of the upper fixing part 86 and the front of the center part 803. The upper end portion of the substrate retaining member 90 is inserted into the first clearance 86a.

The lower fixing part 87 is a plate-form member that is bent stepwise in the side view. The lower fixing part 87 is fixed onto the lower part of the center part 803 by screws. A plurality of the screw holes TH4 that is formed on the lower fixing part 87. Through the screw holes TH4 the lower fixing part 87 is fixed onto the section near the lower end of the substrate retaining member 90 (to be described). A second clearance 87a is formed between a portion of the lower fixing part 87 and the front of the center part 803. The lower end portion of the substrate retaining member 90 is inserted into the second clearance 87a.

The partitioning plate 80 that is configured as above, if viewed from a plane, will show a shape that has been bent in a plurality of places. The reason the partitioning plate 80 is bent like this is to improve the work efficiency when placing the partitioning plate 80. When placed, the partitioning plate 80 is fixed after the partitioning plate 80 is inserted between the bottom plate 31 and the top plate 32 from the side with regard to the main face in the state of placement of the partitioning plate 80. Meanwhile, in the heat source unit 20, as shown in FIG. 6, the vertical part 70 of the fifth refrigerant pipeline P5 that passes heat sink 49 extends in a vertical direction in the electrical components compartment SP2, and the vertical part 70 can be an obstacle when the partitioning plate 80 moves to the placement position. In a planar view, the contact portion of the left side part 801 and the center part 803, and the contact portion of the right side part 802 and the center part 803, of the partitioning plate 80 is configured in a bent shape at the time of the placement of the partitioning plate 80 to avoid contact with the fifth refrigerant pipeline P5.

Here, the placement method of the partitioning plate 80 is described. As shown in FIG. 28, when placing the partitioning plate 80, the partitioning plate 80 is inserted between the bottom plate 31 and the top plate 32 (that is, the inner part of the casing 30) from the side (more specifically on the right side) with regard to the main face (see the arrow mark of the dashed line in FIG. 28). When inserting the partitioning plate 80, the vertical part 70 of the fifth refrigerant pipeline P5 can be an obstacle, but by inserting the left end part into the back side of the vertical part 70, contact between the partitioning plate 80 and the vertical part 70 is avoided. Then, after the insertion of the partitioning plate 80 is performed until the partitioning plate 80 is positioned more to the left than the vertical part 70, the partitioning plate 80 is rotated so that the left side part 801 goes around the vertical part 70 (see the arrow mark of the phantom line in FIG. 28). Specifically, by rotating around the vertical axis in the condition where the partitioning plate 80 is in place, the partitioning plate 80 moves to the placement position, and is then fixed.

That is, when the partitioning plate 80 is placed, the partitioning plate 80 is fixed after the entirety thereof is inserted between the bottom plate 31 and the top plate 32 from the right side with regard to the main face of the partitioning plate 80 in a placed state. Also, when inserted, the partitioning plate 80 is inclined with regard to the main face of the partitioning plate 80 in a placed state. And after being inserted, the partitioning plate 80 moves to the placement position by rotating around the vertical axis in the placed state. As a result, the partitioning plate 80 can easily be placed even after the bottom plate 31 and the top plate 32 are placed. Alternatively, when the partitioning plate 80 is placed, the entirety thereof can be inserted between the bottom plate 31 and the top plate 32 from the left side with regard to the main face of the partitioning plate 80 in a placed state, and then fixed.

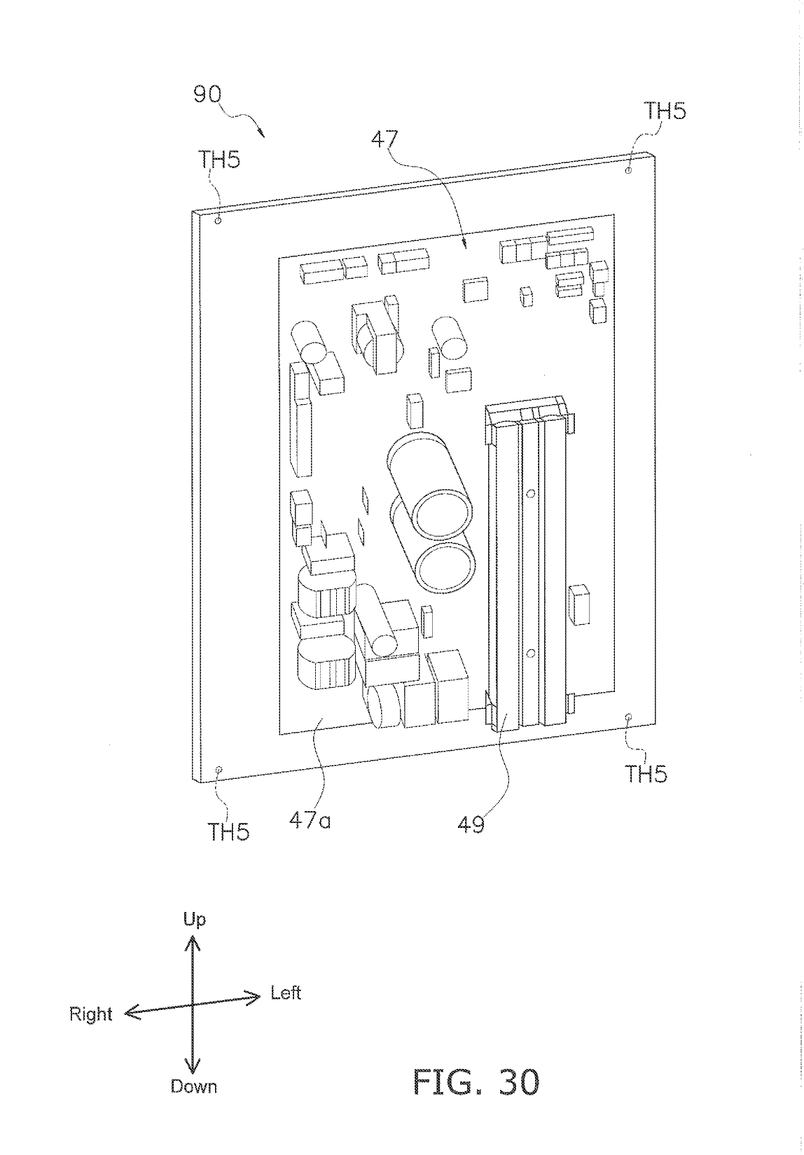

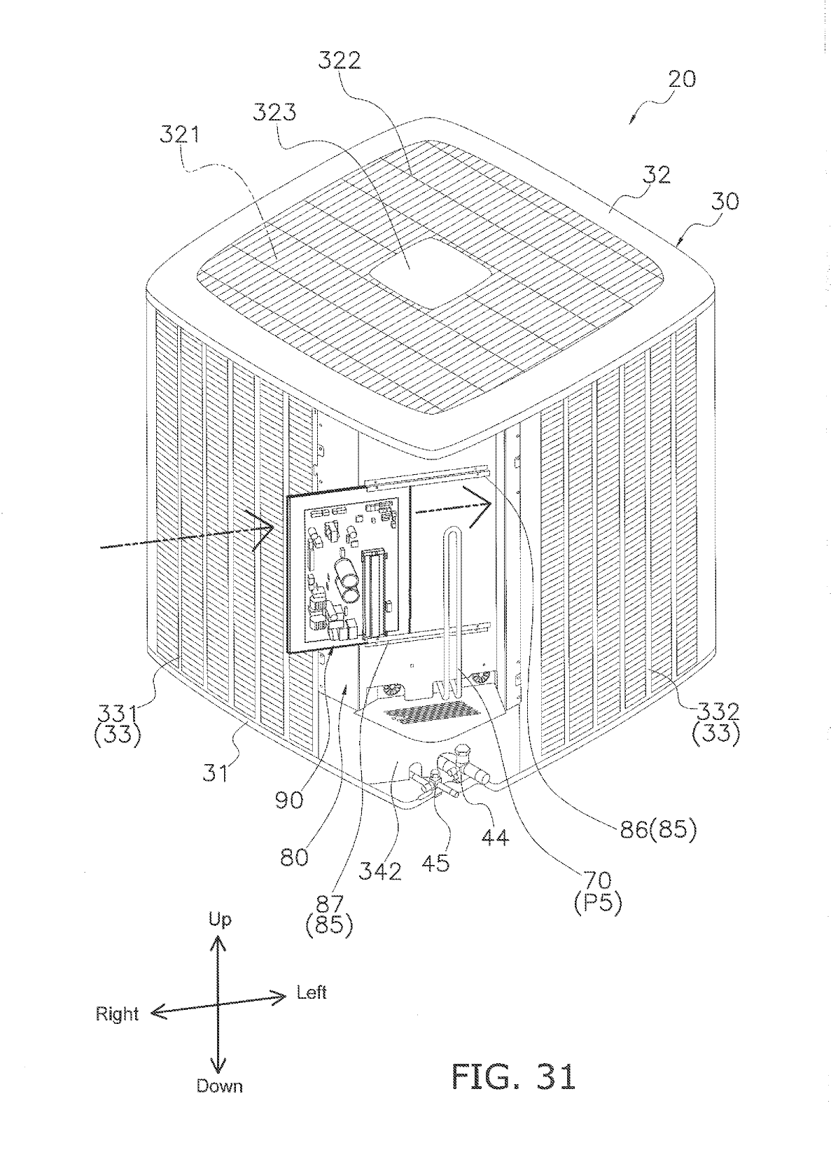

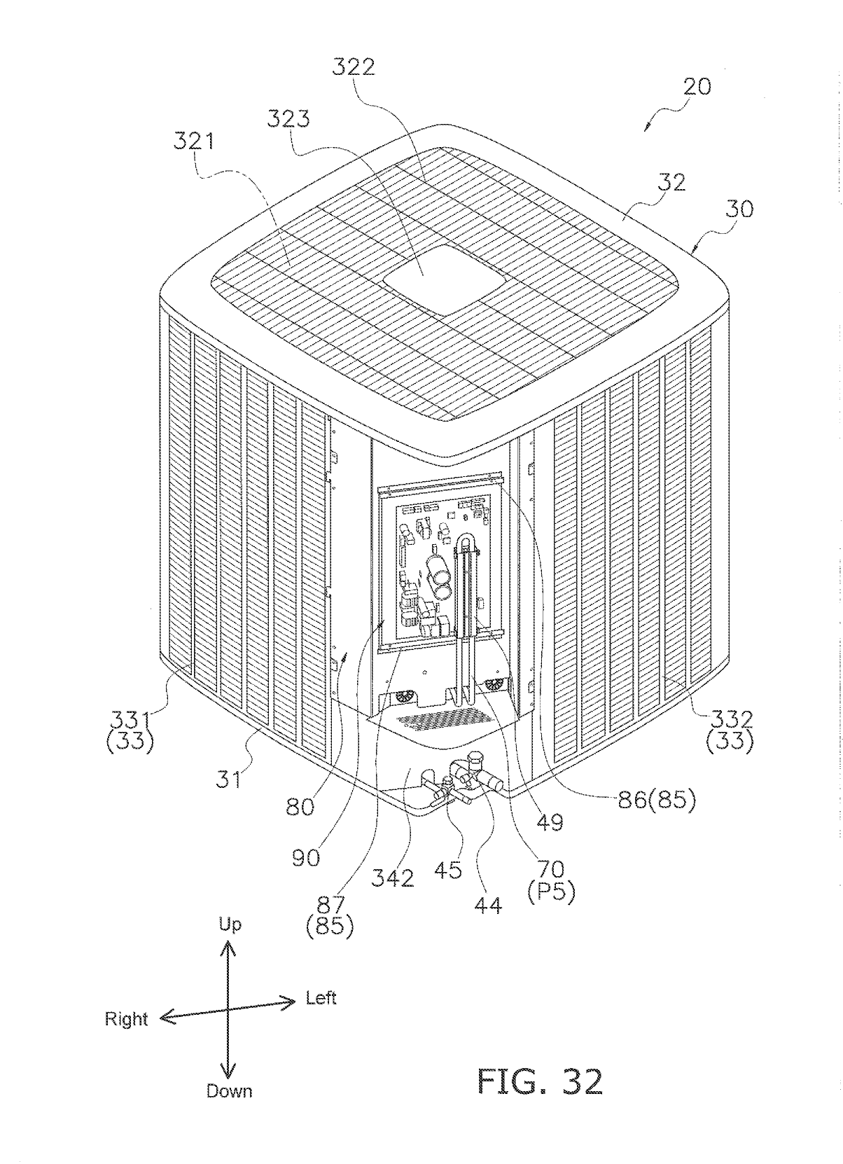

The substrate retaining member 90 is fixed to the front surface of the partitioning plate 80 that has been provided in this manner. FIG. 30 is an external view of the substrate retaining member 90 in a state where the substrate 47a is fixed. FIG. 31 is a diagram illustrating a form where the substrate retaining member 90 is placed on the partitioning plate 80 in the state illustrated in FIG. 29. FIG. 32 is a diagram illustrating a condition where the substrate retaining member 90 is placed on the partitioning plate 80 in the state illustrated in FIG. 29.

The substrate retaining member 90 is a roughly square plate member when viewed from the front surface. The substrate retaining member 90 is mounted and retains the substrate 47a on which the heat source unit controller 47 is implemented on the front face. The screw holes TH5 are formed in the vicinity of the four corners of the substrate retaining member 90. The substrate retaining member 90 is screwed to the substrate fixing part 85 of the partitioning plate 80 through the screw holes TH5.

When the substrate retaining member 90 is placed in position, the lower end of the substrate retaining member 90 is inserted in the second clearance 87a at the same time that the upper end of the substrate retaining member 90 is inserted into the first clearance 86a from. the right side with regard to the main face of the partitioning plate 80, and is moved in the left direction (see the arrow mark of the phantom line in FIG. 31). Furthermore, when movement to the position where the screw holes TH5 are aligned with screw holes TH3 and screw holes TH4 is complete, the substrate retaining member 90 is fixed to the partitioning plate 80 by screws. When placement of the substrate retaining member 90 is complete, a portion of the fifth refrigerant pipeline P5 is stored in the heat sink 49. Note that the substrate 47a where the heat source unit controller 47 is mounted is fixed to the substrate retaining member 90, before the placement of the substrate retaining member 90 in the partitioning plate 80.

1. A heat source unit for a refrigerating apparatus, comprising:
a heat exchanger;
an actuator;
an electrical component configured to control driving of the actuator;
a casing housing the heat exchanger, the actuator, and the electrical component; and
a partitioning plate disposed in the casing,
the casing having a bottom plate and a top plate with a vent formed on the top plate, the vent being configured to vent air upward,
the heat exchanger having
a first side face part,
a second side face part adjoining the first side face part,
a third side face part opposing the first side face part and adjoining the second side face part, and
a fourth side face part opposing the second side face part and adjoining the third side face part,
the first side face part
facing a first side face of the casing, and
having an end part forming one end of the heat exchanger, and
the fourth side face part
facing a second side face of the casing, and
having an end part forming another end of the heat exchanger,
the actuator being disposed in a first space surrounded by the first side face part, the second side face part, the third side face part, the fourth side face part, and the partitioning plate,
the electronic component being disposed in a second space partitioned from the first space by the partitioning plate,
the second space being positioned in a corner formed by the first side face part and the second side face part, and
the partitioning plate
being positioned between an end part of the first side face part and an end part of the fourth side face part, and
being configured to have at least a portion thereof inserted between the bottom plate and the top plate from a side with regard to a main face of the partitioning plate and to be fixed in a placed state after being inserted.

2. The heat source unit for a refrigerating apparatus according to claim 1, wherein
the partitioning plate includes a first part that has a flat plate shape, and
the first part is inserted in a direction along the main face of the partitioning plate in the placed state.

3. The heat source unit for a refrigerating apparatus according to claim 2, wherein
the first part is configured to be inserted inclined with regard to the main face of the partitioning plate in the placed state, and
the first part is configured to be inserted, rotated around a vertical axis in the placed state, and thereby moved to the placed state.

4. The heat source unit for a refrigerating apparatus according to claim 3, wherein
the first part has handle usable when the first part is rotated after being inserted.

5. The heat source unit for a refrigerating apparatus according to claim 2, wherein
the partitioning plate further includes a second part configured to support the first part, the second part
has a larger contour than the first part,
is placed before placing the first part, and
is configured to be inserted between the bottom plate and the top plate from the front face side with regard to the main face of the partitioning plate in the placed state, rotated around a horizontal axis in the placed state and thereby moved to the placed state before being fixed.

6. The heat source unit for a refrigerating apparatus according to claim 3, wherein
the partitioning plate further includes a second part configured to support the first part, the second part
has a larger contour than the first part,
is placed before placing the first part,
is configured to be inserted between the bottom plate and the top plate from the front face side into the main face of the partitioning plate in the placed state, subsequently rotated around a horizontal axis in the placed state and thereby moved to the placed state before being fixed.

7. The heat source unit for a refrigerating apparatus according to claim 6, wherein
an insertion opening into which the first part is inserted is formed in the second part, and
the first part is fixed to the second part after being inserted into the second part through the insertion opening.

8. The heat source unit for a refrigerating apparatus according to claim 7, wherein
a first opening that is equal to or smaller than the main face of the first part is formed in the main face of the second part;
the first part
is fixed to a plate surface on a first space side of the second part,
is exposed to a second space side from the first space side through the first opening, and
has a handle usable when the first part is rotated after insertion;
the handle has a protrusion; and
the protrusion
is positioned at a height at which contact is made with an edge of the first opening when the first part is rotated and moved, and
has a curved surface shaped so as to slide on the edge of the first opening.

9. The heat source unit for a refrigerating apparatus according to claim 1, wherein
a refrigerant pipeline adjoining the partitioning plate is disposed in the second space.

10. The heat source unit for a refrigerating apparatus according to claim 9, wherein
the electronic component is mounted on a substrate; and
the substrate
is fixed to the partitioning plate, and
has a heat sink contacting the refrigerant pipeline.

11. The heat source unit for a refrigerating apparatus according to claim 10, wherein
the refrigerant pipeline includes a vertical part extending in a vertical direction.

12. The heat source unit for a refrigerating apparatus according to claim 1, wherein
the partitioning plate is configured to be fixed after an entirety thereof is inserted between the bottom plate and the top plate from four the side with regard to the main face of the partitioning plate in the placed state.

13. The heat source unit for a refrigerating apparatus according to claim 12, wherein
the partitioning plate is configured to be
inserted inclined with regard to the main face of the partitioning plate in a placed state, and
rotated around a vertical axis in the placed state after being inserted, and thereby moved to the placed state.
